(19) United States
(12) Patent Application Publication
(10) Pub. No.: US 2026/0214895 A1
(43) Pub. Date: Jul. 23, 2026

(54) MEMORY DEVICE INCLUDING TRENCH LINER BETWEEN BLOCKS

(71) Applicant: Micron Technology, Inc., Boise, ID (US)

(72) Inventors: Zhi Qiang Teo, Singapore (SG); Kaiming Luo, Singapore (SG); Wenjie Li, Singapore (SG)

(21) Appl. No.: 19/029,565

(22) Filed: Jan. 17, 2025

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

Some embodiments include apparatuses and methods of forming the apparatuses. One of the methods includes: a structure including a conductive region; first memory cells and first control gates associated with the first memory cells located over the structure; second memory cells and second control gates associated with the second memory cells located over the structure; and a dielectric structure between the first memory cells and the second memory cells and separating the first control gates from the second control gates. The dielectric structure extends into the conductive region and includes a liner adjacent a portion of the conductive region. The liner includes a dielectric constant different from a dielectric constant of silicon dioxide.

### BACKGROUND

Conventional memory devices (e.g., 3-D NAND memory devices) often have blocks of memory cells and dielectric structures that separate one block from another. In forming such memory devices, many manufacturing processes (steps) are used. The dielectric structure and adjacent structures are susceptible to structural degradation during some of the processes used to form some conventional memory devices. Such degradation can impact the structure and reliability of the memory device. Some conventional techniques are designed to prevent such degradation. However, such conventional techniques often increase manufacturing cost.

### BRIEF DESCRIPTION OF THE DRAWINGS

FIG. 1 shows an apparatus in the form of a memory device, according to some embodiments described herein.

FIG. 2 shows a schematic of an apparatus in the form a memory device having a memory array and memory cell blocks, according to some embodiments described herein.

FIG. 3A shows a top view of a structure of the memory device of FIG. 2 including a memory array, staircase regions, and dielectric structures between memory cell blocks of the memory device, according to some embodiments described herein.

FIG. 3B shows a top view of a portion of the memory device of FIG. 3A, according to some embodiments described herein.

FIG. 3C shows a portion (e.g., a side view) in the Y-Z direction of the memory device of FIG. 3B, according to some embodiments described herein.

FIG. 3D shows a portion of the memory device of FIG. 3B including a portion (e.g., a side view) in the X-Z direction of a block and a dielectric structure, according to some embodiments described herein.

FIG. 3E shows another portion of the memory device of FIG. 3B including a portion (e.g., a side view) in the X-Z direction of another block and a dielectric structure, according to some embodiments described herein.

FIG. 4A through FIG. 28 show different views of structures during processes of forming the memory device of FIG. 2 through FIG. 3E, according to some embodiments described herein.

### DETAILED DESCRIPTION

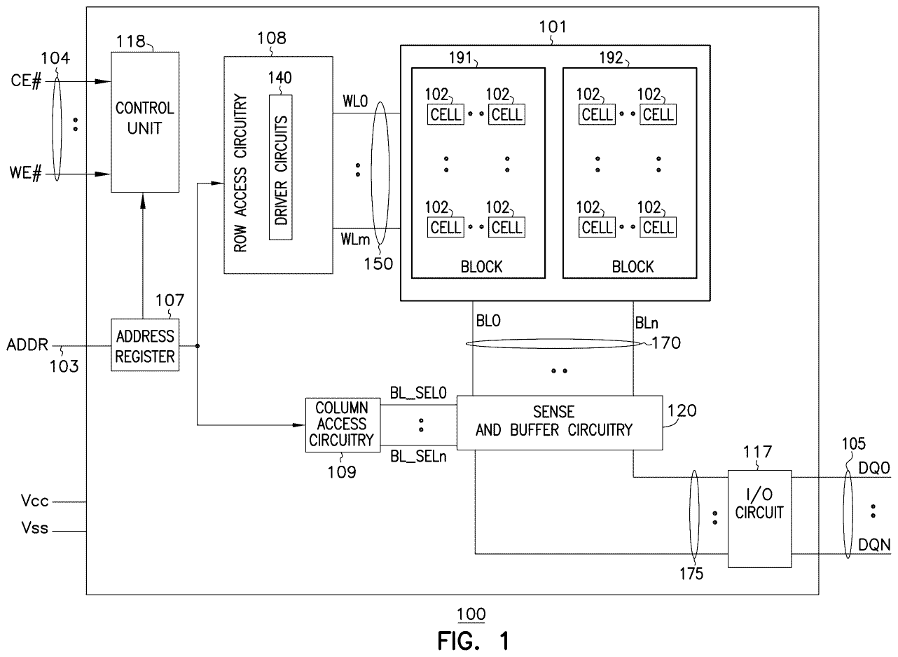

The techniques described herein involve a memory device having blocks of memory cells, dielectric structures between the blocks, and a source structure that includes a conductive region associated with the blocks. The techniques described herein provide improved processes and improved structures associated with the source structure and dielectric structures. In an example, the dielectric structure includes a liner formed to provide structural improvement to part of the memory device adjacent the dielectric structure. The process and structural improvements can lead to reduced cost, and improved reliability and performance of the described memory device. Other improvements and benefits of the described processes and memory devices are further discussed below with reference to FIG. 1 through FIG. 28.

FIG. 1 shows an apparatus in the form of a memory device 100, according to some embodiments described herein. Memory device 100 can include a memory array (or multiple memory arrays) 101 containing memory cells 102 arranged in blocks (blocks of memory cells), such as blocks 191 and 192. In the physical structure of memory device 100, memory cells 102 can be arranged vertically (e.g., stacked one over another) over a substrate (e.g., a semiconductor substrate) of memory device 100. FIG. 1 shows memory device 100 having two blocks 191 and 192 as an example. Memory device 100 can have more than two blocks.

As shown in FIG. 1, memory device 100 can include access lines 150 and data lines 170. Access lines 150 can include word lines, which can include global word lines and local word lines (e.g., control gates). Data lines 170 can include bit lines (e.g., local bit lines). Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks 191 and 192 and data lines 170 to selectively exchange information (e.g., data) with memory cells 102.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which blocks 191 and 192 are to be accessed during a memory operation. Memory device 100 can include drivers (driver circuits) 140, which can be part of row access circuitry 108. Drivers 140 can operate (e.g., operate as switches) to form (or not to form) conductive paths (e.g., current paths) between nodes providing voltages and respective access lines 150 during operations of memory device 100.

Memory device 100 can perform a read operation to read (e.g., sense) information (e.g., previously stored information) from memory cells 102 of blocks 191 and 192, or a write (e.g., programming) operation to store (e.g., program) information in memory cells 102 of blocks 191 and 192. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks 191 and 192.

Memory device 100 can include a control unit 118 that can be configured to control memory operations of memory device 100 based on control signals on lines 104. Examples of the control signals on lines 104 include one or more clock signals and other signals (e.g., a chip-enable signal CE#, a write-enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that may cause memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks 191 and 192 and provide the value of the information to lines 175, which can include global data lines (e.g., global bit lines). Sense and buffer circuitry 120 can also be configured to use signals on lines 175 to determine the value of information to be stored (e.g., programmed) in memory cells 102 of blocks 190 and 191 (e.g., during a write operation) based on the values (e.g., voltage values) of signals on lines 175 (e.g., during a write operation).

Memory device 100 can include input/output (I/O) circuitry 117 to exchange information between memory cells 102 of blocks 191 and 192 and lines (e.g., I/O lines) 105. Signals DQ0 through DQN on lines 105 can represent information read from or stored in memory cells 102 of blocks 191 and 192. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits. A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3-dimensional (3-D) NAND) or a NOR flash memory device, or another kind of memory device, such as a variable resistance memory device (e.g., a phase change memory device or a resistive Random-Access Memory (RAM) device.

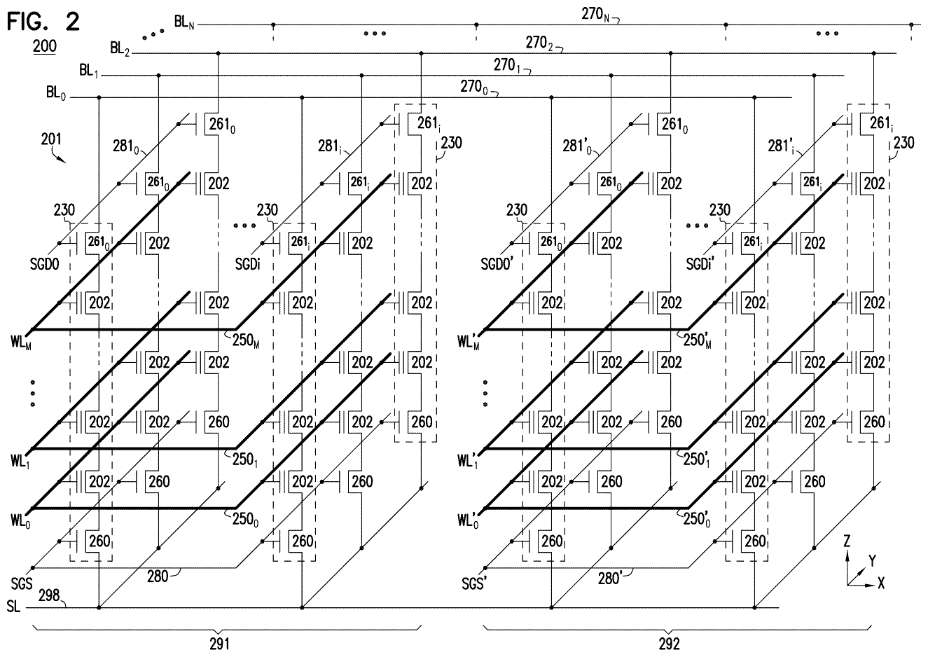

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 28.

FIG. 2 shows a schematic of an apparatus in the form of a memory device 200 having a memory array 201 and blocks (e.g., memory cell blocks) 291 and 292, according to some embodiments described herein. Memory device 200 can include a non-volatile (e.g., NAND flash memory device) or other types of memory devices. Memory device 200 can correspond to memory device 100. For example, memory array (or multiple memory arrays) 201 and blocks 291 and 292 can correspond to memory array 101 and blocks 191 and 192, respectively, of memory device 100 of FIG. 1.

As shown in FIG. 2, memory device 200 can include memory cells 202, data lines 270₀ through 270_{N} (270₀-270_{N}), control gates 250₀ through 250_{M} in block 291, and control gates 250′₀ through 250′_{M} in block 292. Data lines 270₀-270_{N} can correspond to part of data lines 170 of memory device 100 of FIG. 1. In FIG. 2, label “N” (index N) next to a number (e.g., 270_{N}) represents the number of data lines of memory device 200. For example, if memory device 200 includes 16 data lines, then N is 15 (data lines 270₀ through 270₁₅). In FIG. 2, label “M” (index M) next to a number (e.g., 250_{M}) represents the number of control gates of memory device 200. For example, if memory device 200 includes 128 control gates, then M is 127 (control gates 250₀ through 250₁₂₇). Memory device 200 can have the same number of control gates (e.g., M−1 control gates) among the blocks (e.g., blocks 291 and 292) of memory device 200.

In FIG. 2, data lines 270₀-270_{N} can include (or can be part of) bit lines (e.g., local bit lines) of memory device 200. As shown in FIG. 2, data lines 270₀-270_{N} can carry signals (e.g., bit line signals) BL₀ through BL_{N}, respectively. In the physical structure of memory device 200, data lines 270₀-270_{N} can be structured as conductive lines and have respective lengths extending in the X-direction (e.g., a direction from one memory block to another).

As shown in FIG. 2, memory cells 202 can be organized into separate blocks (memory cell blocks or blocks of memory cells) such as blocks 291 and 292. FIG. 2 shows memory device 200 including two blocks 291 and 292 as an example. However, memory device 200 can include numerous blocks. The blocks (e.g., blocks 291 and 292) of memory device 200 can share data lines (e.g., data lines 270₀-270_{N}) to carry information (in the form of signals) read from or to be stored in memory cells of selected memory cells (e.g., selected memory cells in block 291 or 292) of memory device 200.

Control gates 250₀-250_{M} in block 291 can be part of local word lines, which can be part of (or can be coupled to) access lines (e.g., global word lines) of memory device 200 that can correspond to access lines 150 of memory device 100 of FIG. 1. Control gates 250′₀-250′_{M} in block 292 can be another part of other local word lines, which can be part of access lines (e.g., global word lines) of memory device 200. Control gates 250₀-250_{M} can be electrically separated from control gates 250′₀-250′_{M}. Thus, blocks 291 and 292 can be accessed separately (e.g., accessed one at a time). For example, block 291 can be accessed at one time using control gates 250₀-250_{M}, and block 292 can be accessed at another time using control gates 250′₀-250′_{M} at another time.

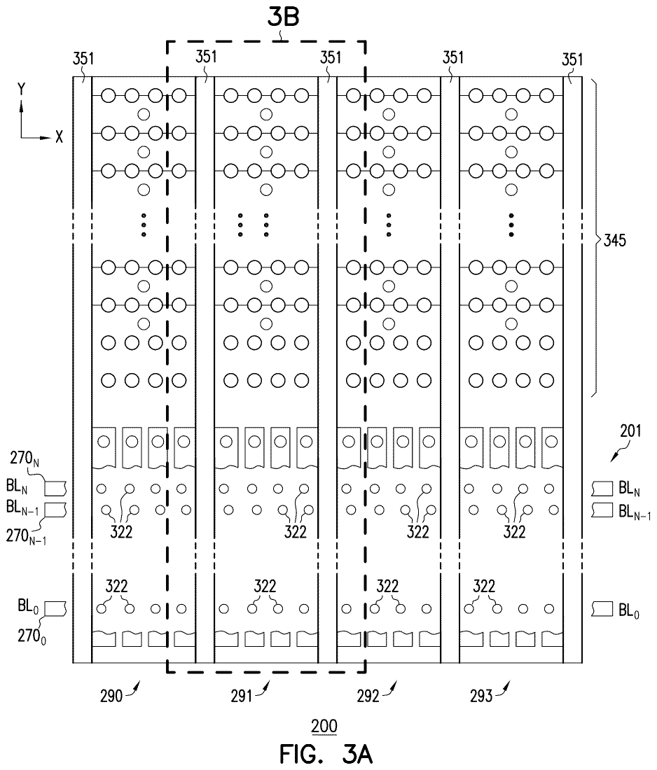

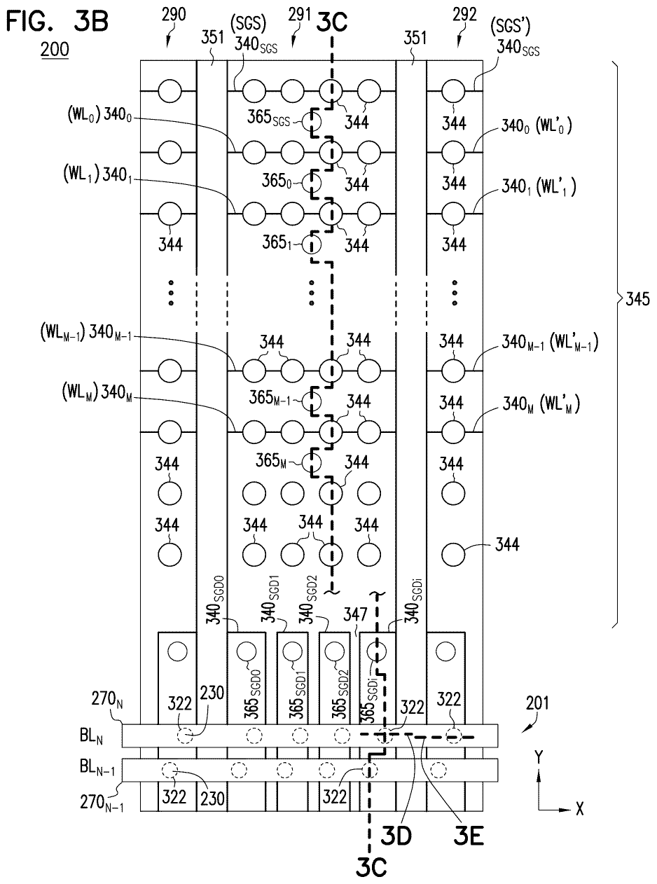

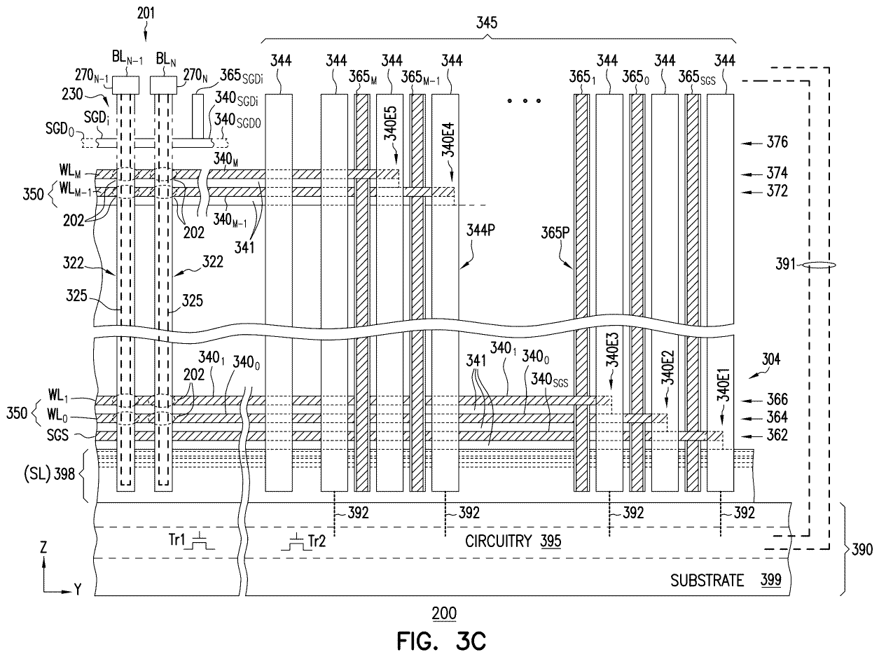

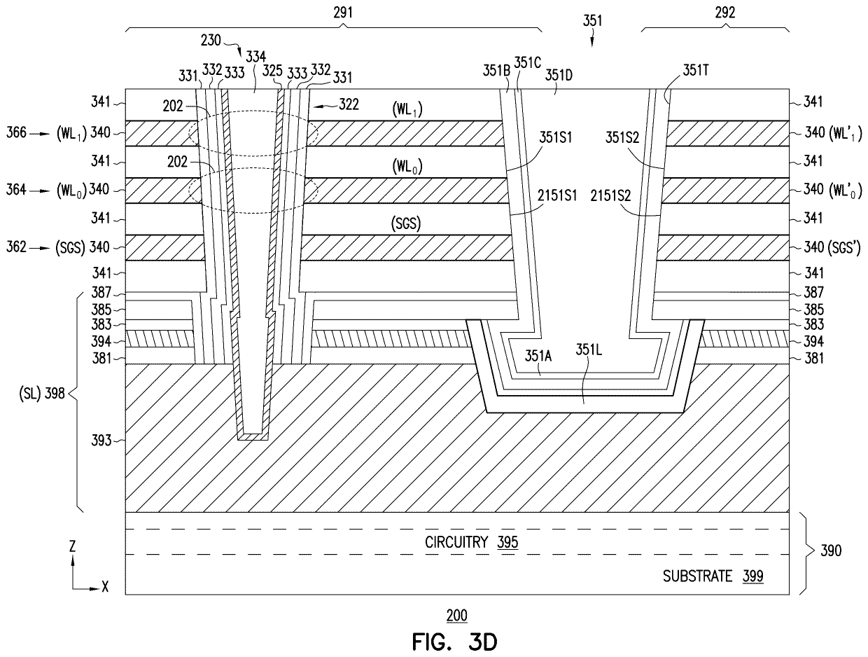

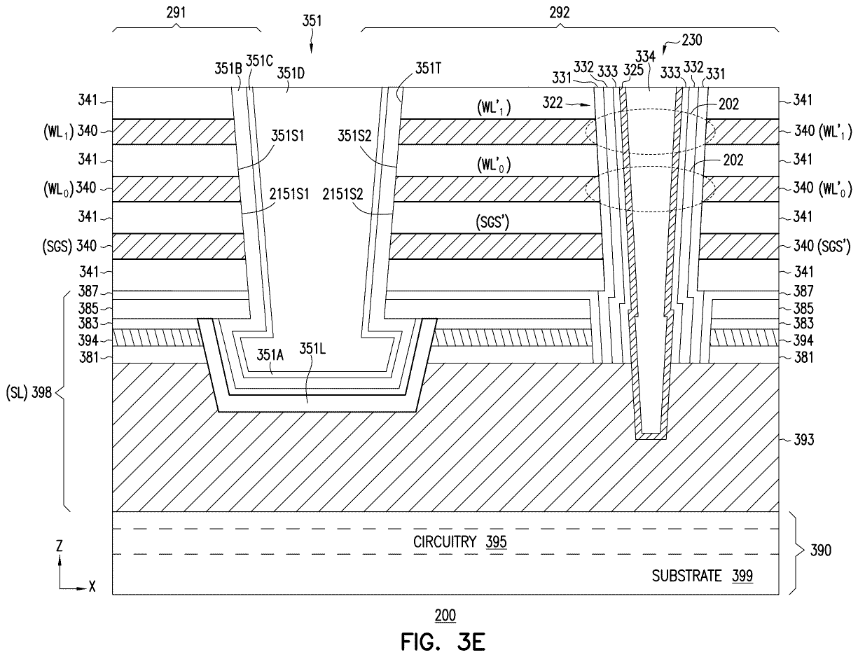

FIG. 2 shows directions X, Y, and Z that can be relative to the physical directions (e.g., dimensions) of the structure of memory device 200. For example, the Z-direction can be a direction perpendicular to (e.g., vertical direction with respect to) a substrate of memory device 200 (e.g., a substrate 399 shown in FIG. 3C). The Z-direction is perpendicular to the X-direction and Y-direction (e.g., the Z-direction is perpendicular to an X-Y plane of memory device 200). In the physical structure of memory device 200, control gates 250₀-250_{M} can be formed on different levels (e.g., layers) of memory device 200 in the Z-direction. In this example, the levels (e.g., layers) of control gates 250₀-250_{M} can be formed (e.g., stacked) one level (one layer of material) over another (another layer of material) in the Z-direction.

As shown in FIG. 2, memory cells 202 can be included in respective memory cell strings 230 in each of the blocks (e.g., blocks 291 and 292) of memory device 200. Each of memory cell strings 230 can have series-connected memory cells (e.g., M+1 (e.g., 128)) series-connected memory cells) in the Z-direction. In a physical structure of memory device 200, memory cells 202 in each of memory cell strings 230 can be formed (e.g., stacked vertically one over another) in different levels (e.g., M+1 (e.g., 128) layers in the example of FIG. 2) in the Z-direction of memory device 200. Memory cells 202 of a respective memory cell string 230 can be associated with a respective memory cell pillar (e.g., pillar 322 shown in FIG. 3C). The number of memory cells in each of memory cell strings 230 can be equal to the number of levels (e.g., layers) of control gates (e.g., control gates 250₀-250_{M}) of memory device 200. For example, if each memory cell string 230 has 128 (e.g., M=127) memory cells 202, then there are 128 corresponding levels of control gates 250₀-250_{M} for the 128 memory cells.

As shown in FIG. 2, control gates 250₀-250_{M} can carry corresponding signals WL₀-WL_{M}. As mentioned above, control gates 250₀-250_{M} can include (or can be parts of) access lines (e.g., word lines) of memory device 200. Each of control gates 250₀-250_{M} can be part of a structure (e.g., a level) of a conductive material (e.g., a layer of conductive material) located in a level of memory device 200. Memory device 200 can use signals WL₀-WL_{M} to selectively control access to memory cells 202 of block 291 during an operation (e.g., read, write, or erase operation). For example, during a read operation, memory device 200 can use signals WL₀-WL_{M} to control access to memory cells 202 of block 291 to read (e.g., sense) information (e.g., previously stored information) from memory cells 202 of block 291. In another example, during a write operation, memory device 200 can use signals WL₀-WL_{M} to control access to memory cells 202 of block 291 to store information in memory cells 202 of block 291.

Like control gates 250₀-250_{M} in block 291, control gates 250′₀-250′_{M} in block 292 can carry corresponding signals WL′₀-WL′_{M}. Each of control gates 250′₀-250′_{M} can be part of a structure (e.g., a level) of a conductive material (e.g., a layer of conductive material) located in a single level of memory device 200. Control gates 250′₀-250′_{M} can be located in the same levels (in the Z-direction) as control gates 250₀-250_{M}, respectively. As mentioned above, control gates 250′₀-250′_{M} (e.g., local word lines) can be electrically separated from control gates 250₀-250_{M} (e.g., other local word lines)

Memory device 200 can use signals WL′₀-WL′_{M} to control access to memory cells 202, respectively, of block 292 during an operation (e.g., read, write, or erase operation). For example, during a read operation, memory device 200 can use signals WL′₀-WL′_{M} to control access to memory cells 202 of block 292 to read (e.g., sense) information (e.g., previously stored information) from memory cells 202 of block 292. In another example, during a write operation, memory device 200 can use signals WL′₀-WL′_{M} to control access to memory cells 202 of block 292 to store information in memory cells 202 block 292.

As shown in FIG. 2, memory cells in different memory cell strings in the same block can share (e.g., can be controlled by) the same control gate in that block. For example, in block 291, memory cells 202 coupled to control gate 250₀ can share (can be controlled by) control gate 250₀. In another example, memory cells 202 coupled to control gate 250₁ can share (can be controlled by) control gate 250₁. In another example, in block 292, memory cells 202 coupled to control gate 250′₀ can share (can be controlled by) control gate 250′₀. In another example, memory cells 202 coupled to control gate 250′₁ can share (can be controlled by) control gate 250′₁.

Memory device 200 can include a source (e.g., a source line, a source plate, or a source region) 298. Source 298 can be part of (or can include) a structure (e.g., source structure) 398 shown in FIG. 3A that can carry a signal (e.g., a source line signal) SL. Source 298 can be common conductive region (e.g., common source plate or common source region) of block 291 and 292. Source 298 can be coupled to a ground connection (e.g., ground plate) of memory device 200. Alternatively, source 298 can be coupled to a connection (e.g., a conductive region) that is different from a ground connection.

As shown in FIG. 2, memory device 200 can include select transistors (e.g., drain select transistors) 261₀ through 261ᵢ (261₀-261ᵢ) and select gates (e.g., drain select gates) 281₀ through 281ᵢ in block 291. Transistors 261₀ can share the same select gate 281₀. Transistors 261ᵢ can share the same select gate 281ᵢ. Select gates 281₀-281ᵢ can carry signals SGD0 through SGDi, respectively.

Transistors 261₀-261ᵢ can be controlled (e.g., turned on or turned off) by signals SGD0-SGDi, respectively. During a memory operation (e.g., a read or write operation) of memory device 200, transistors 261₀ and transistors 261ᵢ can be turned on one group at a time (e.g., either the group of transistors 261₀ or the group of transistors 261ᵢ can be turned on at a time). Transistors 261₀ can be turned on (e.g., by activating respective signals SGD0) to couple memory cell strings 230 of block 291 to respective data lines 270₀-270_{N}. Transistors 261ᵢ can be turned on (e.g., by activating respective signals SGDi) to couple memory cell strings 230 of block 291 to respective data lines 270₀-270_{N}. Transistors 261₀-261ᵢ can be turned off (e.g., by deactivating respective signals SGD0-SGDi) to decouple the memory cell strings 230 of block 291 from respective data lines 270₀-270_{N}.

Memory device 200 can include transistors (e.g., source select transistors) 260 in block 291, each of which can be coupled between source 298 and memory cells 202 in a respective memory cell string (one of memory cell strings 230) of block 291. Memory device 200 can include a select gate (e.g., source select gate) 280. Transistors 260 in block 291 can share select gate 280. Transistors 260 in block 291 can be controlled (e.g., turned on or turned off) by the same signal, such as SGS signal (e.g., source select gate signal) provided on select gate 280. During a memory operation (e.g., a read or write operation) of memory device 200, transistors 260 in block 291 can be turned on (e.g., by activating an SGS signal) to couple the memory cell strings of block 291 to source 298. Transistors 260 in block 291 can be turned off (e.g., by deactivating the SGS signal) to decouple the memory cell strings of block 291 from source 298.

Memory device 200 can include similar elements among the blocks (e.g., blocks 291 and 292). For example, in block 292, memory device 200 can include select gates (e.g., drain select gates) 281′₀ through 281′ᵢ, and transistors (e.g., drain select transistors) 261₀-261ᵢ. Transistors 261₀ of block 292 can share the same select gate 281′₀. Transistors 261ᵢ of block 292 can share the same select gate 281′ᵢ. Select gates 281′₀ through 281′ᵢ can carry signals SGD0′ through SGDi′, respectively. Transistors 261₀-261ᵢ of block 292 can be controlled (e.g., turned on or turned off) by signals SGD0′ through SGDi′, respectively. During a memory operation (e.g., a read or write operation) of memory device 200, the group of transistors 261₀ and the group of transistors 261ᵢ of block 292 can be turned on (e.g., by activating respective signals SGD0′ through SGDi′) one group at a time to couple respective memory cell strings of block 292 to data lines 270₀-270_{N}. Transistors 261₀-261ᵢ of block 292 can be turned off (e.g., by deactivating respective signals SGD0′ through SGDi′) to decouple the memory cell strings of block 292 from respective sets of data lines 270₀-270_{N}.

Memory device 200 can include transistors (e.g., source select transistors) 260 in block 292, each of which can be coupled between source 298 and the memory cells in a respective memory cell string of block 292. Transistors 260 of block 292 can share the same select gate (e.g., source select gate) 280′ of memory device 200. Transistors 260 of block 292 can be controlled (e.g., turned on or turned off) by the same signal, such as SGS′ signal (e.g., source select gate signal) provided on select gate 280′. During a memory operation (e.g., a read or write operation) of memory device 200, transistors 260 of block 292 can be turned on (e.g., by activating an SGS′ signal) to couple the memory cell strings of block 292 to source 298. Transistors 260 of block 292 can be turned off (e.g., by deactivating the SGS′ signal) to decouple the memory cell strings of block 292 from source 298. FIG. 2 shows select gates 280 and 280′ being electrically separated from each other as an example. Alternatively, select gates 280 and 280′ can be electrically coupled to each other.

Memory device 200 includes other components, which are not shown in FIG. 2 so as not to obscure the example embodiments described herein. Some of the structures of memory device 200 are described below with reference to FIG. 3A through FIG. 28. For simplicity, detailed description of the same element among the drawings (FIG. 1 through FIG. 28) is not repeated.

FIG. 3A shows a top view of a structure of memory device 200 including a memory array 201, a region 345, and dielectric structures (e.g., block dividers) 351 between respective blocks 290, 291, 292, and 293, according to some embodiments described herein. In the figures (drawings) herein, similar or the same elements of memory device 200 of FIG. 2 and other figures (e.g., FIG. 3A through FIG. 28) are given the same labels. Detailed descriptions of similar or the same elements may not be repeated from one figure to another figure. For simplicity, cross-sectional lines (e.g., hatch lines) are omitted from some or all of the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 3A, blocks (blocks of memory cells) 290, 291, 292, and 293 (290-293) of memory device 200 can be located side-by-side from one block to another in the X-direction. Four blocks 290-293 are shown as an example. Memory device 200 can include numerous blocks. Blocks 291 and 292 of FIG. 3A are schematically shown and described above with reference to FIG. 2. Other blocks (e.g., block 290 and 293) of memory device 200 in FIG. 3A are not shown in FIG. 2.

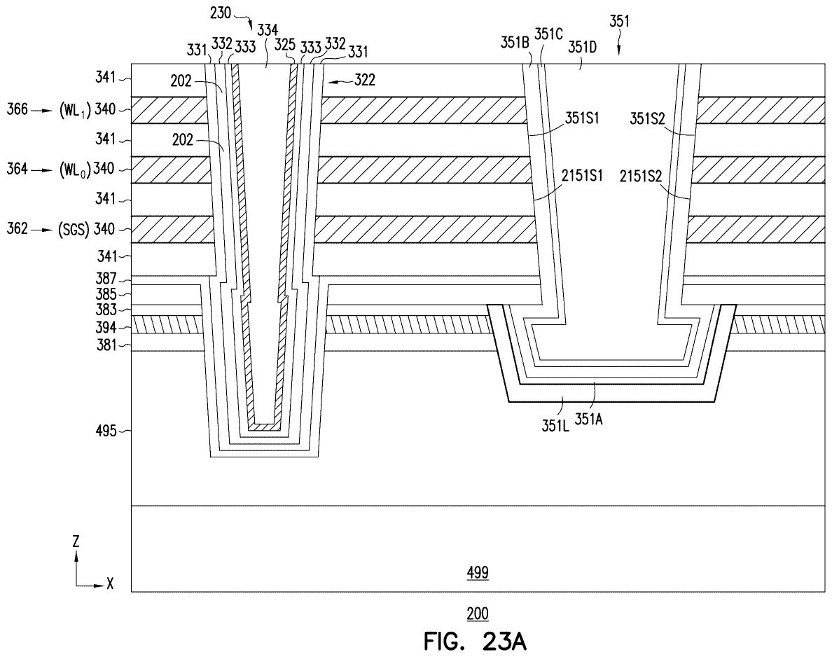

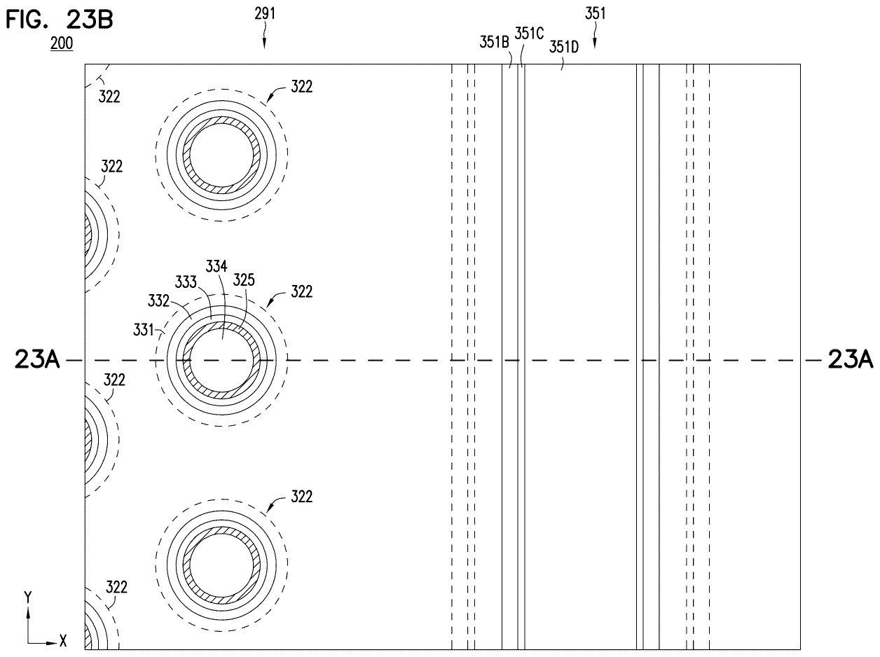

In FIG. 3A, dielectric structures 351 can be formed to divide (e.g., organize) memory device 200 into physical blocks (e.g., blocks 290-293). Dielectric structures 351 can have lengths extending in the Y-direction. Each of dielectric structures 351 can be formed in (or can be located in) a trench (e.g., a slit) between two adjacent blocks. FIG. 23A shows an example of such a trench (e.g., trench 2151T) having a depth in the Z-direction and opposing sidewalls (e.g., edges) adjacent respective blocks.

In FIG. 3A, each of dielectric structures 351 can include a dielectric material (or dielectric materials) formed in (e.g., filling) a respective trench. Dielectric structures 351 can separate (e.g., physically and electrically separate) one block from another. For example, as shown in FIG. 3A, dielectric structure 351 between blocks 290 and 291 can separate block 291 from block 290. Dielectric structure 351 between blocks 291 and 292 can separate block 291 from block 292.

In FIG. 3A, data lines 270₀ through 270_{N} are partially shown for simplicity. Data lines 270₀ through 270_{N} (associated with signals BL₀ through BL_{N}) of memory device 200 can be located over pillars 322 (shown in top view) of blocks 290-293 (with respect to the Z-direction). Data lines 270₀ through 270_{N} can have respective lengths extending in the X-direction. Data lines 270₀ through 270_{N} can extend over (e.g., on top of) and across (in the X-direction) blocks 290-293 and can be shared by blocks 290-293.

Region 345 of memory device 200 can be called a staircase region at which the control gates of a respective block have edges that form a staircase structure (e.g., staircase structure 304 shown in FIG. 3C). Region 345 can be part of memory device 200 where conductive contacts (e.g., conductive contacts 365_{SGS}, 365₀, 365₁, 365_{M}, 365_{M-1}, 365_{SGD0}, and 365_{SGDi} shown in FIG. 3B) of memory device 200 can be formed. The conductive contacts can provide electrical connections (e.g., signals) to respective select gates (e.g., select gates 280, 281₀ and 281ᵢ in FIG. 2) and control gates (e.g., control gates 250₀ through 250_{M} in FIG. 2) in respective blocks 290, 291, 292, and 293 of memory device 200. In FIG. 3A, region 345 can also include other structures (e.g., structures 344, described below). A portion labeled “3B” in FIG. 3A is shown in detail in FIG. 3B.

As shown in FIG. 3B, memory device 200 can include pillars 322 (shown in top view) in each of the blocks (e.g., block 290, 291, and 292). Pillars 322 are memory cell pillars, which are different from the pillars of structures 344 of memory device 200. Pillars 322 are part of respective memory cell strings 230 (also schematically shown in FIG. 2) of memory device 200.

As shown in FIG. 3B, pillars (memory cell pillars) 322 can be located under (below) and coupled to respective data lines (only data lines 270_{N-1} and 270_{N} are shown). Memory cells 202 of a memory cell string can be located (e.g., can be formed vertically) long the length (shown in FIG. 3C) of a corresponding pillar 322. Pillars 322 of blocks 290-293 can share data lines 270₀ through 270_{N}.

As shown in FIG. 3A and FIG. 3B, data lines 270₀ through 270_{N} (associated with signals BL₀ through BL_{N}) of memory device 200 can be located over (above) pillars 322 (and over associated memory cell strings) in memory array 201. Data lines 270₀ through 270_{N} can be coupled to respective pillars 322 (which are located under data lines 270₀ through 270_{N} in the Z-direction).

As mentioned above, memory device 200 can include structures 344. As shown in FIG. 3B, structures 344 can be adjacent respective conductive contacts 365_{SGS}, 365₀, 365₁, 365_{M}, 365_{M-1}, 365_{SGD0}, and 365_{SGDi}. For simplicity, in FIG. 3B, only some of structures 344 are labeled. As shown in FIG. 3B, conductive contacts 365_{SGS}, 365₀, 365₁, 365_{M}, 365_{M-1}, 365_{SGD0}, 365_{SGD1}, 365_{SGD2}, and 365_{SGDi} can have a circular shape (e.g., a circular cross-section viewed from a direction perpendicular to the X-Y plan). Structures 344 can also have a circular shape (e.g., a circular cross-section viewed from a direction perpendicular to the X-Y plan).

As mentioned above, conductive contacts 365_{SGS}, 365₀, 365₁, 365_{M}, 365_{M-1}, 365_{SGD0}, 365_{SGD1}, 365_{SGD2}, and 365_{SGDi} in FIG. 3B can be formed to provide electrical connections (e.g., signals) to respective select gates (e.g., select gates 280, 281₀ and 281ᵢ in FIG. 2) and control gates (e.g., control gates 250₀ through 250_{M} of FIG. 2) of memory device 200.

Some of structures 344 in FIG. 3B can be formed to provide electrical connections (e.g., to form part of respective conductive paths) between circuitry (e.g., circuitry 395 in FIG. 3C) of memory device 200 and other elements of memory device 200. For example, some of structures 344 can be part of conductive paths (not shown) between data lines 270₀ through 270_{N} and circuitry 395).

Some other structures 344 can be called support structures (e.g., support pillars). The support structures (some of structures 344) are formed to provide support (structural support) for part of memory device 200 (e.g., region 345) during fabrication of memory device 200. The support structures are electrically uncoupled to other elements (e.g., circuitry) of memory device 200.

As shown in FIG. 3B, memory device 200 can include conductive materials 340_{SGS}, 340₀, 340₁, 340_{M-1}, 340_{M}, 340_{SGD0}, 340_{SGD1} and 340_{SGD2} and 340_{SGDi} in block 291 that can form (e.g., can be materials included in) respective select gate (e.g., source select gate) 280, control gates 250₀ through 250_{M}, and select gates (e.g., drain select gates) 281₀ and 281ᵢ in FIG. 2) of block 291. In FIG. 3B, conductive materials 340_{SGD0} and 340_{SGDi} can form two of the four respective drain select gates (e.g., drain select gates 280₀ and 280ᵢ in FIG. 2) of block 291. Conductive materials 340_{SGD1} and 340_{SGD2} in FIG. 3B can form the other two of the four drain select gates of block 291 (e.g., not shown in FIG. 2).

As shown in FIG. 3B, conductive materials 340_{SGD0}, 340_{SGD1}, 340_{SGD2}, and 340_{SGDi} (FIG. 3B) can be electrically separated from each other by a gap 347 (which can be filled with a dielectric material (or materials)). For simplicity, only one gap 347 is labeled in FIG. 3B.

As shown in FIG. 3B, like block 291, block 292 also include conductive materials 340₀, 340₁, 340_{M-1}, and 340_{M} that are electrically separated (electrically and physically separated) from conductive materials 340₀, 340₁, 340_{M-1}, and 340_{M} of block 291 by dielectric structure 351 between blocks 291 and 292. In block 292, conductive materials 340₀, 340₁, 340_{M-1}, and 340_{M} can form respective control gates (associated with signals WL′₀ through WL′_{M}) of block 292. Different portions (e.g., side views) of memory device 200 along In FIG. 3B, lines 3C-3C, line 3D, and line 3C are shown in FIG. 3C, FIG. 3D, and FIG. 3E, respectively.

FIG. 3C shows a portion (e.g., a side view) in the Y-Z direction of memory device 200 along line 3C-3C of FIG. 3B. FIG. 3D shows a portion of memory device 200 including a portion (e.g., a side view) in the X-Z direction of block 291 and dielectric structure 351 between blocks 291 and 292 at location associated with line 3D in FIG. 3B. FIG. 3E shows a portion of memory device 200 including a portion (e.g., a side view) in the X-Z direction of block 292 and dielectric structure 351 between blocks 291 and 292 at location associated with line 3E in FIG. 3B.

As shown in FIG. 3C, memory device 200 can include levels 362, 364, 366, 372, 374, and 376 that are physical levels (e.g., layers) in the Z-direction of memory device 200. Conductive materials 340_{SGS}, 340₀, 340₁, 340_{M-1}, 340_{M}, and 340_{SGDi} can be located (e.g., stacked) one level (e.g., one layer) over another in respective levels 362, 364, 366, 372, 374, and 376 in the Z-direction. Conductive materials 340_{SGS}, 340₀, 340₁, 340_{M-1}, 340_{M}, and 340_{SGDi} can also be called levels of conductive materials 340_{SGS}, 340₀, 340₁, 340_{M-1}, 340_{M}, and 340_{SGDi}. As shown in FIG. 3C, conductive materials 340_{SGD0}, 340 _{SGD1}, 340 _{SGD2}, and 340_{SGDi} (340_{SGD1} and 340_{SGD2} are not shown) can be located on the same level (e.g., level 376).

As shown in FIG. 3C, conductive materials 340_{SGS}, 340₀, 340₁, 340_{M-1}, 340_{M}, and 340_{SGDi} can interleave with dielectric materials (levels of dielectric materials) 341 in the Z-direction. Conductive materials 340_{SGS}, 340₀, 340₁, 340_{M-1}, 340_{M}, and 340_{SGDi} can include metal (e.g., tungsten, or other metal), other conductive materials, or a combination of conductive materials. Dielectric materials 341 can include silicon dioxide.

Signals SGS, WL₀, WL₁, WL_{M-1}, WL_{M}, SGD₀, and SGDᵢ in FIG. 3C associated with respective conductive materials are the same signals shown in FIG. 2. Conductive material 340_{SGS} can form select gate 280 (associated with signal SGS) of FIG. 2. As shown in FIG. 3C, conductive materials 340₀, 340₁, 340_{M-1}, and 340_{M} can form control gates 250₀ through 250_{M} (associated with signals WL₀, WL₁, WL_{M-1}, and WL_{M}, respectively). Conductive material 340_{SDG0} and 340_{SGDi} (associated with signals SGD₀, and SGDᵢ) can form select gates 281₀ and 281ᵢ, respectively.

FIG. 3C shows an example of memory device 200 including one level of conductive materials 340_{SGS} that forms a select gate (e.g., source select gate associated with signal SGS). However, memory device 200 can include multiple levels (similar to level 362) of conductive materials (e.g., multiple levels of conductive material 340_{SGS}) located under (in the Z-direction) the level of conductive materials 340₁ (e.g., below level 364) to form multiple source select gates of memory device 200.

FIG. 3C shows an example of memory device 200 including one level (e.g., level 376) of multiple drain select gates (on the same level, formed by respective conductive materials 340_{SGD0} through SGDᵢ). However, memory device 200 can include multiple levels (similar to level 376) in which each of such multiple levels can include multiple drain select gates (e.g., four drain select gates in each of the multiple levels).

As shown in FIG. 3C, memory device 200 can include staircase structure 304 located in region (e.g., staircase region) 345. For simplicity, only a portion of staircase structure 304 is shown in FIG. 3C (e.g., a middle portion of staircase structure 304 is omitted from FIG. 3C). As shown in FIG. 3C, respective portions (e.g., end portions) of conductive materials 340_{SGS}, 340₀, 340₁, 340_{M-1}, 340_{M}, and 340_{SDG1} and their respective edges (e.g., steps (or risers)) 340E1, 340E2, and 340E3, 340E4, and 340E5) can collectively form staircase structure 304. As shown in FIG. 3C, dielectric materials 341 can also include edges (not labeled) adjacent (e.g., aligned in the Z-direction with) respective edges 340E1 through 340E5. Thus, staircase structure 304 can also be formed in part by portions and edges of dielectric materials 341.

FIG. 3C also shows tiers 350 of memory device 200. Each tier 350 can include a level of conductive material (e.g., conductive material 340₁) and an adjacent level of dielectric material 341 (e.g., dielectric material 341 between conductive materials 340₀ and 340₁). As shown in FIG. 3C, tiers 350 can be located (e.g., stacked) one over another in the Z-direction over substrate 399. Each tier 350 can have respective memory cells 202 (which are located on the same level (same tier) with respect to the Z-direction) and a respective control gate (e.g., formed by a respective conductive material among conductive materials 340₀, 340₁, 340_{M-1}, and 340_{M}). FIG. 3C shows a few tiers of memory device 200 for simplicity. However, memory device 200 can include up to hundreds of tiers (or more than hundreds of tiers).

Other blocks (e.g., blocks 290, 292, and 293 in FIG. 3B) of memory device 200 can also have their own tiers of memory cells 202 and respective control gates (e.g., respective word lines) associated with the tiers the memory cells, and staircase structures similar to staircase structure 304 in block 291 in FIG. 3C. For simplicity, details of staircase structures of the other blocks (e.g., blocks 290, 292, and 293) of memory device 200 are omitted from the description herein.

As shown in FIG. 3C, structure (e.g., source structure) 398 (which include source 298 of FIG. 2) can include multiple levels (e.g., multiple layers) of different materials stacked one over another over a base structure 390 of memory device 200. For simplicity, the multiple levels of structure 398 are shown in dashed lines. The multiple levels can include a combination of dielectric material (or dielectric materials), semiconductor material (or semiconductor materials), and conductive material (or conductive materials). FIG. 3D (described below) shows details of structure 398.

As shown in FIG. 3C, base structure 390 is adjacent structure (e.g., source structure) 398. Base structure 390 can include substrate 399. Substrate 399 can include a semiconductor (e.g., silicon) substrate. Substrate 399 can also include circuitry 395. Circuitry 395 can include circuit elements (e.g., transistors Tr1 and Tr2 shown in FIG. 3C) coupled to other elements of memory device 200. The other elements can include data lines 270₀ through 270_{N} (shown in FIG. 3A); conductive contacts 365_{SGS}, 365₀, 365₁, 365_{M}, 365_{M-1}, and 365_{SGDi} (and conductive contacts 365_{SGD0}, 365 _{SGD1}, and 365 SGD2 shown in FIG. 3B); conductive structures 392, conductive paths 391 and other (not shown) conductive connections; and other circuit elements of memory device 200. The circuit elements (e.g., transistors Tr1 and Tr2) of circuitry 395 can be configured to perform part of a function of memory device 200. For example, transistors Tr1 and Tr2 can be part of decoder circuits, driver circuits, buffers, sense amplifiers, charge pumps, and other circuitry of memory device 200.

As shown in FIG. 3C, conductive paths (e.g., conductive routings) 391 can include portions extending in the Z-direction (e.g., extending vertically). Conductive paths 391 can include (e.g., can be coupled to) at least some of the conductive contacts (e.g., conductive contacts 365_{SGS}, 365₁, 365_{M}, 365_{M-1}, and 365_{SGDi}). As shown in FIG. 3C, conductive paths 391 can be coupled to circuitry 395. For example, at least one of conductive paths 391 can be coupled to at least of one of transistors Tr1 and Tr2 of circuitry 395.

Conductive paths 391 and conductive structures 392 can provide electrical connections between elements of memory device 200. For example, conductive paths 391 can be coupled to conductive contacts 365_{SGS}, 365₀, 365₁, 365_{M}, 365_{M-1}, and 365_{SGDi}, and circuit elements (e.g., word line drivers and word line decoders, not shown) of circuitry 395 to provide electrical connections (e.g., in the form of signals SGS, WL₀, WL₁, WL_{M-1}, WL_{M}, and SGDᵢ) from circuit elements (e.g., word line drivers, word line decoders, and charge pumps, not shown) in circuitry 395 to conductive contacts 365_{SGS}, 365₀, 365₁, 365_{M}, 365_{M-1}, and 365_{SGDi}, respectively.

As shown in FIG. 3C, conductive contacts 365_{SGS}, 365₀, 365₁, 365_{M}, and 365_{M-1} can include respective pillars (conductive pillars) 365P extending in the Z-direction (e.g., extending vertically). Conductive contacts 365_{SGS}, 365₀, 365₁, 365_{M}, and 365_{M-1} (including a respective pillar) can contact (form an electrical connection with) respective conductive materials 340_{SGS}, 340₀, 340₁, 340_{M-1}, and 340_{M}. Conductive contacts 365_{SGS}, 365₀, 365₁, 365_{M}, and 365_{M-1} can be part of conductive paths (e.g., part of conductive paths 391) to carry electrical signals to the select gate (e.g., source select gate associated with signal SGS), the control gates (e.g., control gates associated with signals WL_{M} and WL_{M-1}), respectively.

As shown in FIG. 3C, conductive contact 365_{SGS} can contact conductive material 340_{SGS} and electrically separated from the rest of conductive materials (e.g., conductive materials 340₀, 340₁, 340_{M-1}, 340_{M}, and 340_{SGDi}). Conductive contact 365₀ can contact conductive material 340₀ and electrically separated from the rest of conductive materials (e.g., conductive materials 340_{SGS}, 340₁, 340_{M-1}, 340_{M}, and 340_{SGDi}). Thus, a conductive contact (e.g., conductive contact 365₀) can be electrically in contact with only one of the conductive materials among the conductive materials (e.g., conductive materials 340_{SGS}, 340₀, 340₁, 340_{M-1}, 340_{M}, 340_{SGD0}, and 340_{SGDi} in FIG. 3C) of memory device 200.

As shown in FIG. 3C, conductive contacts 365_{SGS}, 365₀, 365₁, 365_{M}, and 365_{M-1} can extend into structure 398. However, conductive contacts 365_{SGS}, 365₀, 365₁, 365_{M}, and 365_{M-1} are electrically separated from structure 398.

As shown in FIG. 3C, structures 344 can include respective pillars 344P that can have lengths extending in the Z-direction (e.g., extending vertically). Structures 344 (including pillars 344P) can have the same length. Structures 344 can go through conductive materials 340_{SGS}, 340₀, 340₁, 340_{M-1}, and 340_{M} and dielectric materials 341. Structures 344 are electrically uncoupled (electrically isolated from) conductive materials 340_{SGS}, 340₀, 340₁, 340_{M-1}, and 340_{M}.

As shown in FIG. 3C, some of structures 344 can be coupled to (e.g., electrically coupled to) elements (e.g., transistors Tr1 and Tr2) of circuitry 395 through respective conductive structures 392. For simplicity, conductive structures 392 are symbolically shown in FIG. 3C as dashed lines. However, each conductive structure 392 can include a conductive material (or a combination of conductive materials). Conductive structures 392 can be coupled to (or can be part of) conductive paths 391.

As shown in FIG. 3C, some of structures 344 are not coupled to conductive structures 392 and not coupled to circuitry 395. These structures 344 (not coupled to circuitry 395) are support structures (e.g., support pillars) to provide structural support to region 345 of memory device 200, as mentioned above in the description of FIG. 3B.

FIG. 3D shows a portion of memory device 200 including a portion in the X-Z direction of block 291 and dielectric structure 351 between blocks 291 and 292 at location associated with line 3D in FIG. 3B. As shown in FIG. 3D, memory cells 202 and associated control gates (associated with signals WL₀ and WL₁) of block 291 can be located over structure 398 and located on one side (e.g., left side) of dielectric structure 351. FIG. 3E (described below) shows memory cells 202 and associated control gates (associated with signals WL′₀ and WL′₁) of block 292 that are located over structure 398 and located on another side (e.g., right) of dielectric structure 351.

In FIG. 3D, for simplicity, some of the conductive materials 340_{SGS}, 340₀, 340₁, 340_{M-1}, and 340_{M} of FIG. 3C are labeled as conductive materials 340 (without subscripts) in FIG. 3D. However, signals SGS, WL₀, and WL₁ associated with conductive materials 340 are the same as those shown in FIG. 3C.

As shown in FIG. 3D, structure 398 can include a conductive region (conductive material) 393, a material 394, and materials 381, 383, 385, and 387. These materials are located on respective levels of memory device 200 and are stacked one over base structure 390 (which include substrate 399 and circuitry 395). Material 394 can include polysilicon. Each of materials 381, 383, 385, and 387 can include a dielectric material (e.g., silicon dioxide).

Conductive region 393 can include conductively doped semiconductor materials or other conductive materials. Example materials of conductively doped semiconductor materials for conductive region 393 include conductively doped polysilicon (e.g., n-doped polysilicon), conductively doped (e.g., n-doped) germanium, conductively doped (e.g., n-doped) silicon-germanium (SiGe).

As shown in FIG. 3D, pillar (memory pillar) 322 can include a conductive channel portion 325 along the length (in the Z-direction) of pillar 322. Pillar 322 can also include a dielectric portion 331, a charge storage portion 332, and a dielectric portion 333 adjacent each other and located along the length of pillar 322. Conductive channel portion 325 can include a conductive polysilicon portion (e.g., conductively doped polysilicon portion).

As shown in FIG. 3D, pillar 322 of block 291 can extend through materials 381, 383, 385, and 387, and 394 of structure 398. At least a portion (e.g., conductive channel portion 325) of pillar 322 of block 291 can also extend at least partially into conductive region 393 of structure 398. For example, pillar 322 of block 291 can include a bottom portion (including part of conductive channel portion 325) that can extend at least partially into conductive region 393 and can be adjacent (e.g., can contact) conductive region 393. Conductive channel portion 325 can be part of a conductive path between a respective data line (e.g., data line 270_{N} in FIG. 3C) and conductive region 393 to carry current (e.g., current between data line 270_{N} and conductive region 393 during an operation (e.g., read, write, or erase) of memory device 200.

FIG. 3D shows an example where pillar 322 includes dielectric portion 331, charge storage portion 332, and dielectric portion 333 (e.g., three layers) between conductive channel portion 325 and respective control gates (associated with signals WL₀ and WL₁). However, in an example, pillar 322 can have a TANOS (TaN, Al₂O₃, Si₃N₄, SiO₂, Si) structure (or a structure similar to a TANOS structure) in which the TANOS structure can have a different number of layers (e.g., more than three layers) of materials. In this example (pillar 322 having a TANOS structure), dielectric portion 331, charge storage portion 332, and dielectric portion 333 can be part of the TANOS structure of pillar 322. In the TANOS structure, dielectric portion 331 (e.g., interpoly dielectric portions) can include a charge blocking material or materials (e.g., a dielectric material including TaN and Al₂O₃) that are capable of blocking a tunneling of a charge. Charge storage portion 332 can include a charge storage element (e.g., charge storage material or materials, e.g., Si₃N₄) that can provide a charge storage function (e.g., trap charge) to represent a value of information stored in memory cells 202. Dielectric portion 333 can include a tunnel dielectric material or materials (e.g., SiO₂) that are capable of allowing tunneling of a charge (e.g., electrons). As an example, dielectric portion 333 can allow tunneling of electrons from conductive channel portion 325 to charge storage portion 332 during a write operation and tunneling of electrons from charge storage portion 332 to conductive channel portion 325 during an erase operation of memory device 200.

In another example, pillar 322 can have a SONOS (Si, SiO₂, Si₃N₄, SiO₂, Si) structure, such that dielectric portion 331, charge storage portion 332, and dielectric portion 333 can be part of the SONOS structure of pillar 322.

In another example, pillar 322 can have a floating-gate structure, such that dielectric portion 331, charge storage portion 332, and dielectric portion 333 can be part of the floating-gate structure of pillar 322. For example, charge storage portion 332 can include polysilicon (or other material) where charge storage portion 332 can be part of a floating gate of a respective memory cell 202.

As shown in FIG. 3D, memory device 200 can include a trench 351T formed between blocks 291 and 292, and dielectric structure 351 located in (formed in) trench 351T. Trench 351T is part of trench 2151T (FIG. 23A). As shown in FIG. 3D, dielectric structure 351 can include a sidewall 351S1 and a sidewall 351S2 opposite sidewall 351S1 in the X-direction. Sidewall 351S1 is adjacent sidewall 2151S1 of trench 351T. Sidewall 351S2 is adjacent sidewall 2151S2 of trench 351T. As shown in FIG. 3D, sidewall 351S1 is adjacent the control gates (associated with signals WL₀ and WL₁) of block 291. Sidewall 351S2 is adjacent the control gates (associated with signals WL′₀ and WL′₁) of block 292.

As shown in FIG. 3D, dielectric structure 351 can include a liner 351L, and portions 351A, 351B, 351C, and 351D formed in trench 351T. Liner 351L can be called trench liner. Portions 351A, 351B, and 351C can be called dielectric portion or dielectric liners.

As shown in FIG. 3D, dielectric structure 351 can extend through materials 381, 383, 385, and 387, and 394 of structure 398. Dielectric structure 351 can also extend at least partially into conductive region 393 of structure 398. For example, liner 351L of dielectric structure 351 can extend at least partially into conductive region 393 and can be adjacent (e.g., can contact) conductive region 393.

As shown in FIG. 3D, portion 351A can be between liner 351L and portion 351B. Portion 351A can include a dielectric material (e.g., silicon dioxide).

Portion 351B can be between liner 351L and portion 351C. Portion 351B can also be between portion 351A and portion 351C. Portion 351B can include a dielectric material (e.g., silicon nitride).

Portion 351C can be between liner 351L and portion 351D. Portion 351B can also be between portion 351A and portion 351C (or between portions 351B and 351D). Portion 351C can include a dielectric material (e.g., silicon dioxide).

Portion 351D can include a dielectric material (e.g., silicon dioxide) or a semiconductor material (e.g., polysilicon or a combination of silicon and Germanium (SiGe)).

In an alternative structure of memory device 200, at least one (one or more) of portions 351A, 351B, 351C, and 351D can be omitted from (e.g., not formed in or not present in) dielectric structure 351. For example, either portions 351B or 351C or both can be omitted.

In FIG. 3D, the material of liner (e.g., trench liner) 351L is different from the materials of portions 351A, 351B, and 351C. The material of liner 351L can be different from silicon dioxide (SiO). For example, the material of liner 351L can be different from material 381 (e.g., silicon dioxide). Therefore, liner 351L can include a dielectric constant that is different from a dielectric constant of silicon dioxide.

The material of liner 351L can also be different from silicon nitride (SiN). Therefore, liner 351L can include a dielectric constant that is different from a dielectric constant of silicon nitride. Thus, liner 351L can include a dielectric constant that is different from a dielectric constant of silicon dioxide and different from a dielectric constant of silicon nitride.

In an example, liner 351L can include boron material. For example, liner 351L can include a combination of a semiconductor material and boron material. In this example, the semiconductor material can include polysilicon. Thus, as an example, liner 351L can include a combination of boron and polysilicon. Liner 351L can include other materials (that are different from silicon dioxide and silicon nitride).

FIG. 3E shows a portion of memory device 200 including a portion in the X-Z direction of block 292 and dielectric structure 351 between blocks 291 and 292 at location associated with line 3E in FIG. 3B. Dielectric structure 351 is the same dielectric structure 351 shown in FIG. 3D. The portion of memory device 200 of FIG. 3E include elements similar to or the same as portion of memory device 200 of FIG. 3D. Thus, the descriptions of similar or the same elements are not repeated. As shown in FIG. 3E, block 292 can have pillar 322 that are the same as pillar 322 of block 291.

As shown in FIG. 3E, pillar 322 of block 292 can extend through materials 381, 383, 385, and 387, and 394 of structure 398. At least a portion (e.g., conductive channel portion 325) of pillar 322 of block 292 can also extend at least partially into conductive region 393 of structure 398. For example, pillar 322 of block 292 can include a bottom portion (including part of conductive channel portion 325) that can extend at least partially into conductive region 393 and adjacent (e.g., contact) conductive region 393.

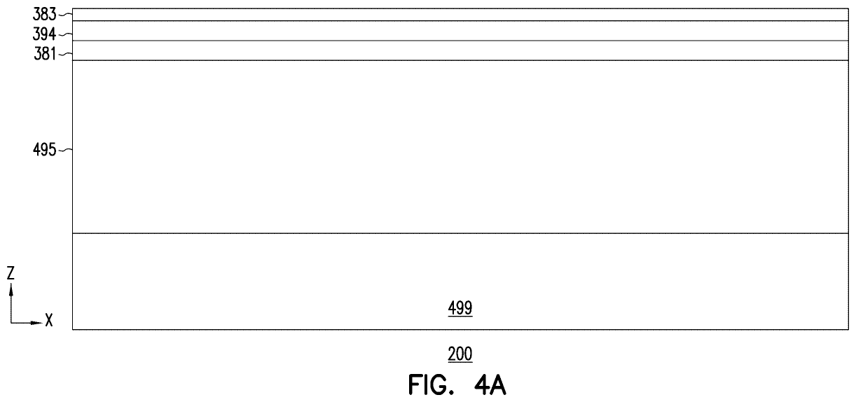

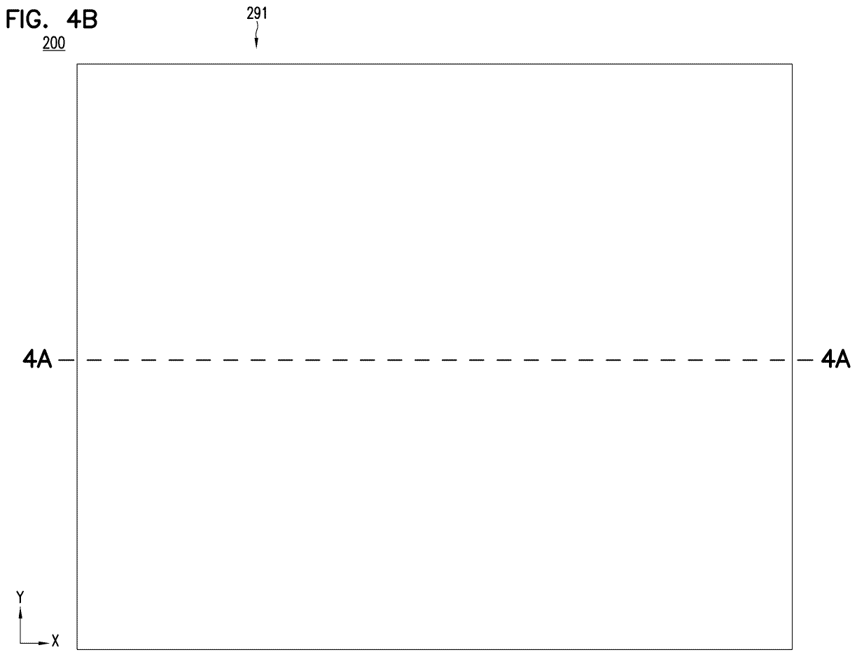

FIG. 4A through FIG. 28 show different views of structures during processes of forming memory device 200 of FIG. 2 through FIG. 3E, according to some embodiments described herein. In FIG. 4A through FIG. 28, the materials and elements that are the same as those in FIG. 2 through FIG. 3E are given the same labels.

For simplicity, the processes associated with FIG. 4A through FIG. 28 involve formation of elements (e.g., pillar 322) of part of block 291 and adjacent dielectric structure 351. Other elements of the other blocks (e.g., block 290, 292, and 293 in FIG. 3A) and other dielectric structures 351 (FIG. 3A) of memory device 200 can be formed using similar (or the same) processes described below with reference to FIG. 4A through FIG. 28.

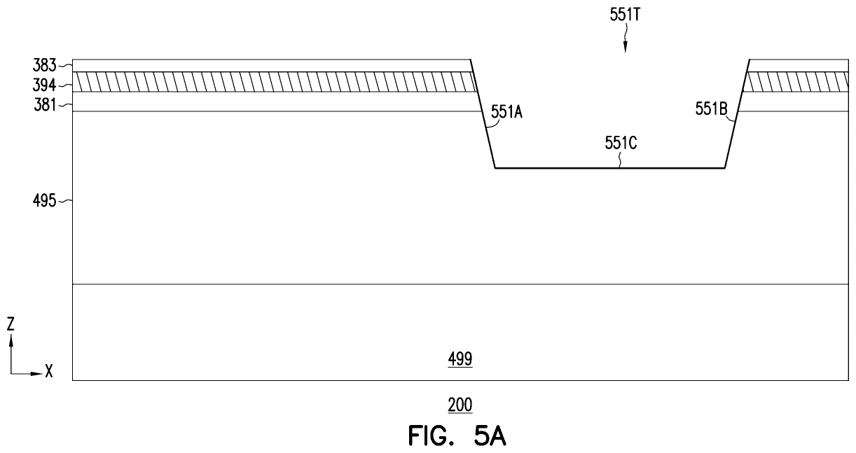

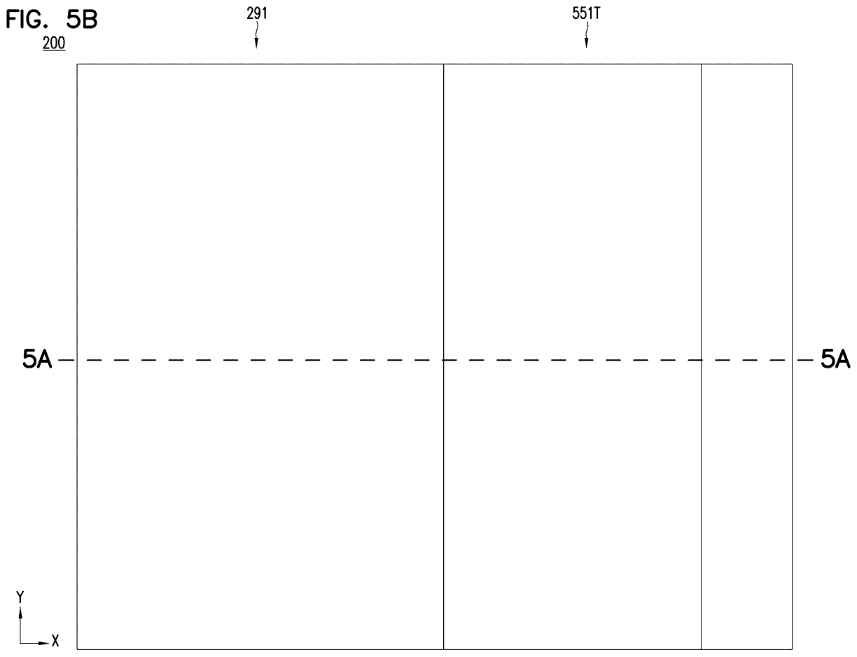

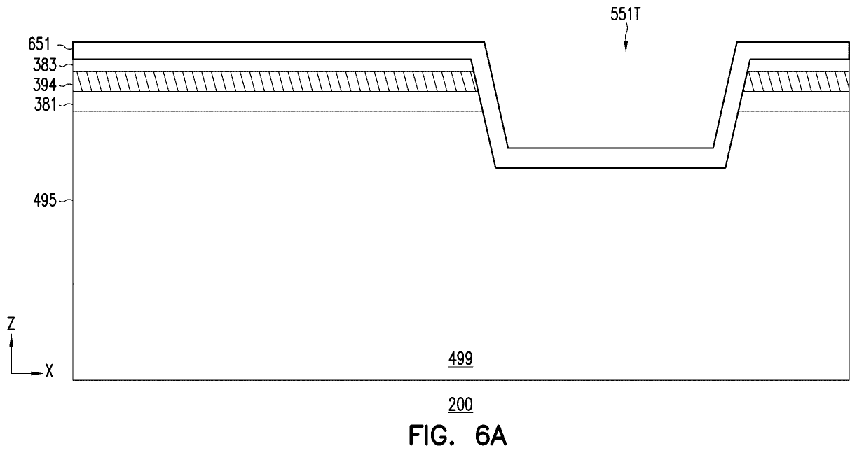

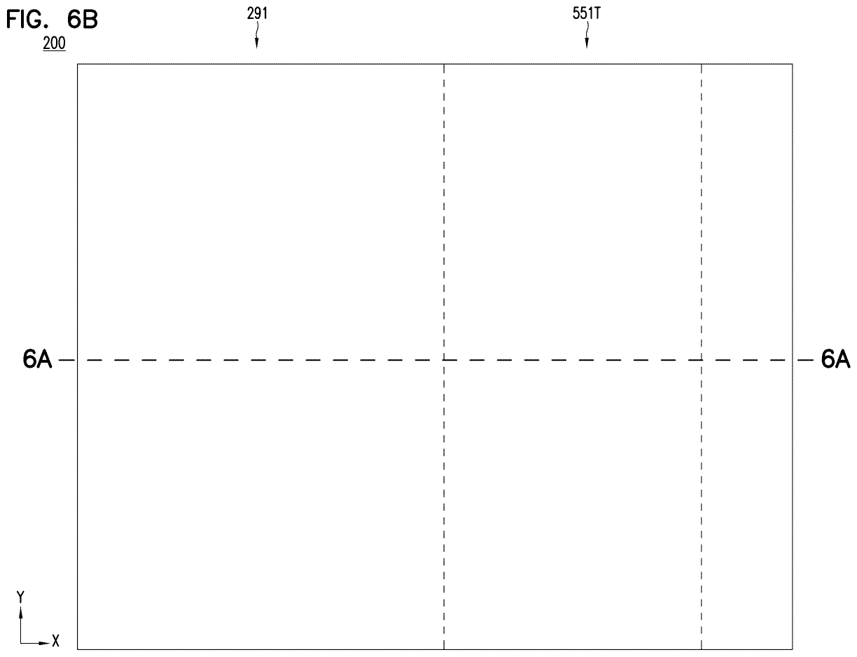

FIG. 4A shows a side view (e.g., a cross-section) of memory device 200 taken along line 4A of FIG. 4B. FIG. 4B shows a top view of memory device 200. The views of memory device 200 shown in FIG. 5A through FIG. 28 follow the same pattern of views of FIG. 4A and FIG. 5B. For example, FIG. 5A shows a similar view (e.g., top view of memory device 200) of FIG. 4A. FIG. 5B shows a similar view (e.g., side view of memory device 200) of FIG. 4B. Line 5A-5A (cross-section line) in FIG. 5B shows the location of the view of memory device 200 of FIG. 5A. In another example, FIG. 6A shows a similar view (e.g., top view of memory device 200) of FIG. 5A. FIG. 6B shows a similar view (e.g., side view of memory device 200) of FIG. 5B. Line 6A-6A (cross-section line) in FIG. 6B shows the location of the view of memory device 200 of FIG. 6A. For simplicity, the names of the views (e.g., side view and top view) are not repeated in FIG. 5A through FIG. 28.

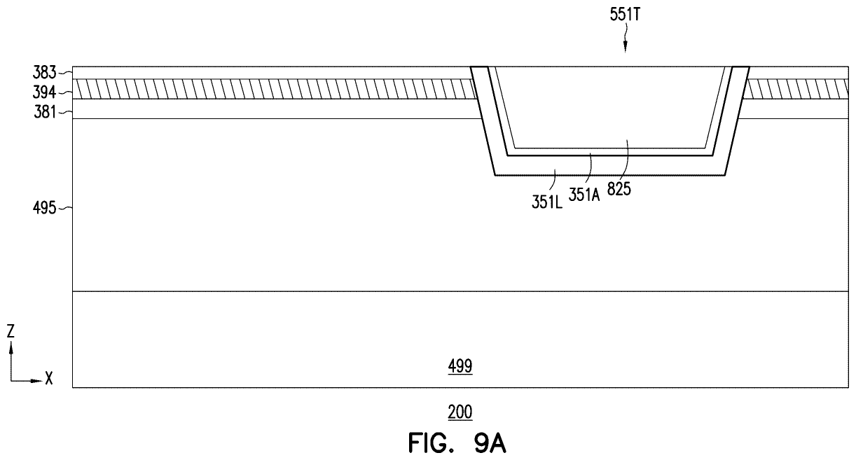

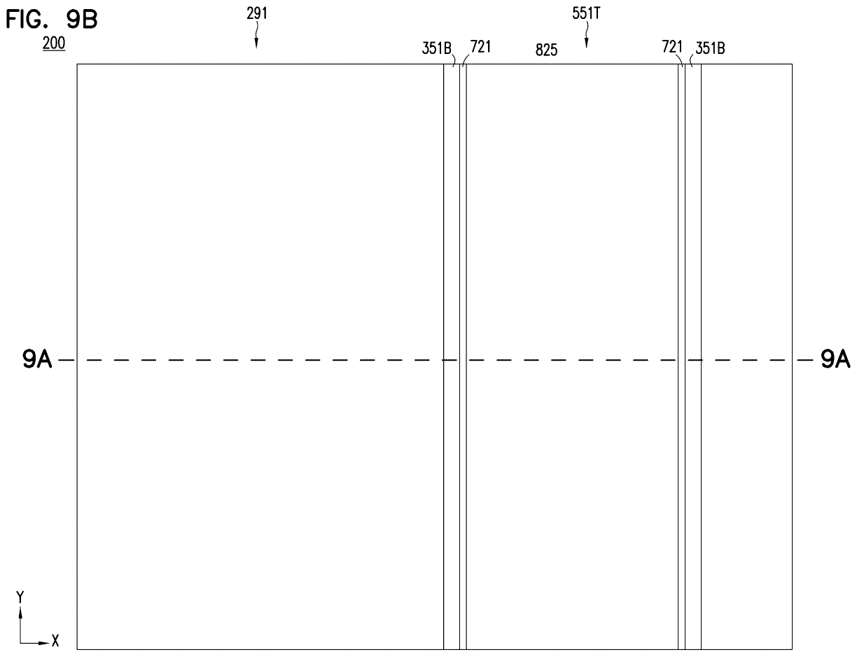

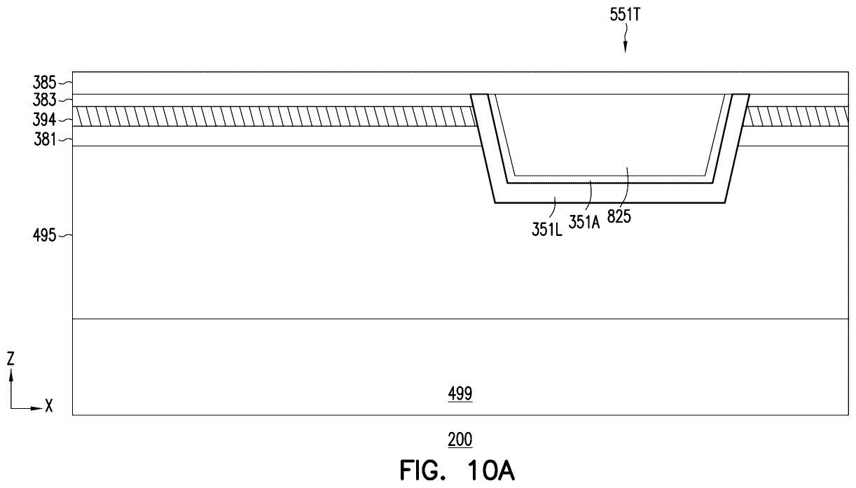

FIG. 4A and FIG. 4B show memory device 200 after levels of materials (e.g., layers of materials) are formed over a structure 499. Structure 499 can include a semiconductor structure (e.g., silicon). In FIG. 4A, the levels of materials formed over structure 499 can include a material 495 and materials 381, 394, and 383. Material 495 can include polysilicon. Materials 381, 394, and 383 are described above with reference to FIG. 3D. For example, material 394 can include polysilicon. Materials 381 and 383 can include dielectric materials (e.g., silicon dioxide). In FIG. 4A, materials 495, 381, 394, and 383 can be sequentially formed one material after another over structure 499. For example, material 383 can be formed first over structure 499 and conductive material 386 can be formed last. Material 383 can be formed to serve as a stop layer in subsequent processes (e.g., a chemical mechanical polishing or planarization (CMP) process in FIG. 9A).

FIG. 5A and FIG. 5B show memory device 200 after a trench 551T is formed in materials 495, 381, 394, and 383. For simplicity, FIG. 4A through FIG. 28 omits details of other portions of memory device 200, such as the portion of block 292 (not labeled) on the right side (in the X-direction) of trench 551T in FIG. 5A and FIG. 5B.

In FIG. 5A and FIG. 5B, forming trench 551T can include removing (e.g., etching) a portion of each in materials 381, 394, 383, and 495 at the locations of trench 551T. As shown in FIG. 5A, trench 551T can include a side (e.g., sidewall) 551A, a side (e.g., sidewall) 551B opposite from side 551A, and a side (e.g., bottom) 551C adjoining sides 551A and 551B. As shown in FIG. 5A, the remaining portion of material 495 can be adjacent (can be part of) sides 551A, 551B, and 551C of trench 551T.

FIG. 5A and FIG. 5B show an example of formation of one trench 551T for simplicity. However, the processes associated with FIG. 5A and FIG. 5B can form (e.g., concurrently form) many trenches 551T, in which each trench 551T can be formed at a location between two adjacent blocks (e.g., between blocks 290 and 291, between blocks 291 and 292, or between blocks 292 and 293 in FIG. 3A). In FIG. 5A and FIG. 5B, trench 551T (and the other trenches not shown in FIG. 5A and FIG. 5B) can be part of (or can include part of) respective dielectric structures 351 (that will be subsequently formed, as described below) between respective blocks of memory device 300 of FIG. 3A.

FIG. 6A and FIG. 6B show memory device 200 after a material 651 is formed in trench 551T over material 495 and on sides 551A, 551B, and 551C of trench 351T. Material 651 may not fill trench 551T. As shown in FIG. 6A, material 651 can be a relatively thin layer of material relative to the thickness (in the Z-direction) of material 495. For example, material 651 can be formed as a liner adjacent (e.g., conformal to) sides 551A, 551B, and 551C of trench 351T.

Material 651 is subsequently processed (in FIG. 9A) to form liner (e.g., trench liner) 351L (FIG. 3D and FIG. 3E). Thus, material 651 is the same as the material of liner 351L. For example, material 651 can be different from silicon dioxide (SiO) and silicon nitride. Thus, material 651 can include a dielectric constant that is different from a dielectric constant of silicon dioxide and a dielectric constant of silicon nitride.

Forming material 651 can include forming (e.g., depositing) a semiconductor material on sides 551A, 551B, and 551C of trench 351T and concurrently adding (e.g., using an in situ process to add) an additional material to the semiconductor material (e.g., concurrently doping the semiconductor material with the additional material). Thus, in an example, material 651 can include a combination of a semiconductor material and additional material. In an example, the additional material includes boron. Thus, in an example, material 651 can include a combination of a semiconductor material and boron material.

In an example, the semiconductor material includes polysilicon (or other semiconductor materials). In an example, the additional material includes boron (or other similar materials). Thus, in an example, material 651 can include a combination of polysilicon and boron.

In subsequent processes (FIG. 9A), a portion of material 651 (e.g., a portion outside trench 551T) is removed and a remaining portion of material 651 in trench 551T forms (becomes) liner 351L (also shown in FIG. 3D and FIG. 3E).

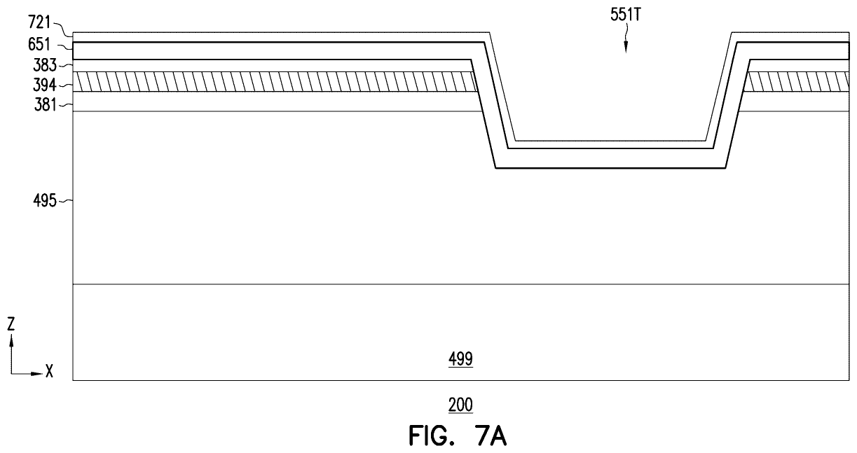

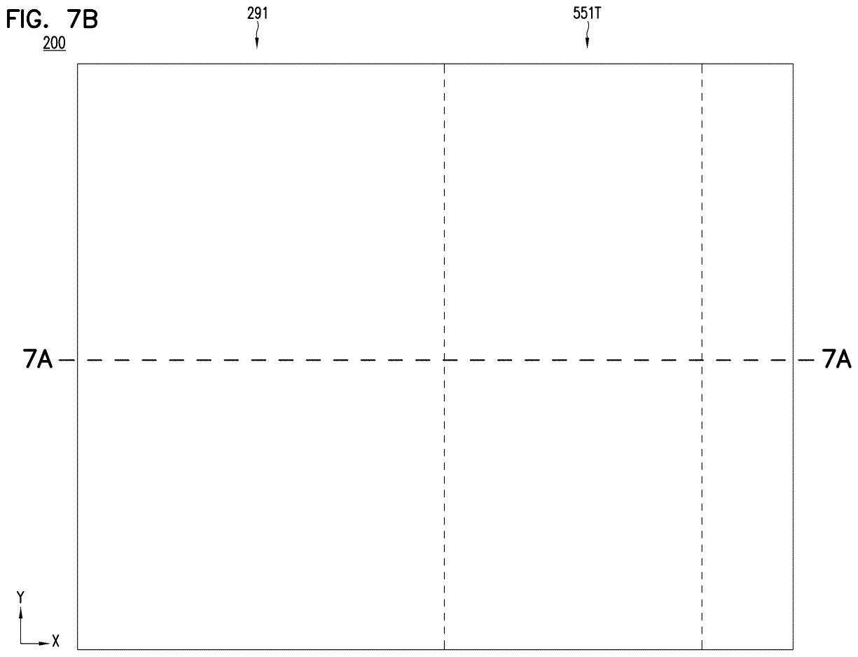

FIG. 7A and FIG. 7B show memory device 200 after a material 721 is formed over material 651. As shown in FIG. 7A, material 721 can be a relatively thin layer of material adjacent material 651. Material 721 can include a dielectric material (e.g., silicon dioxide).

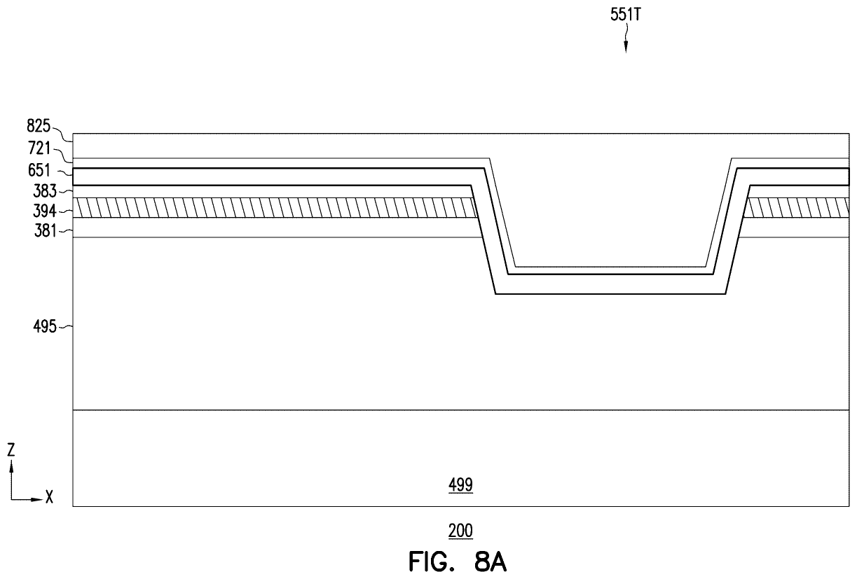

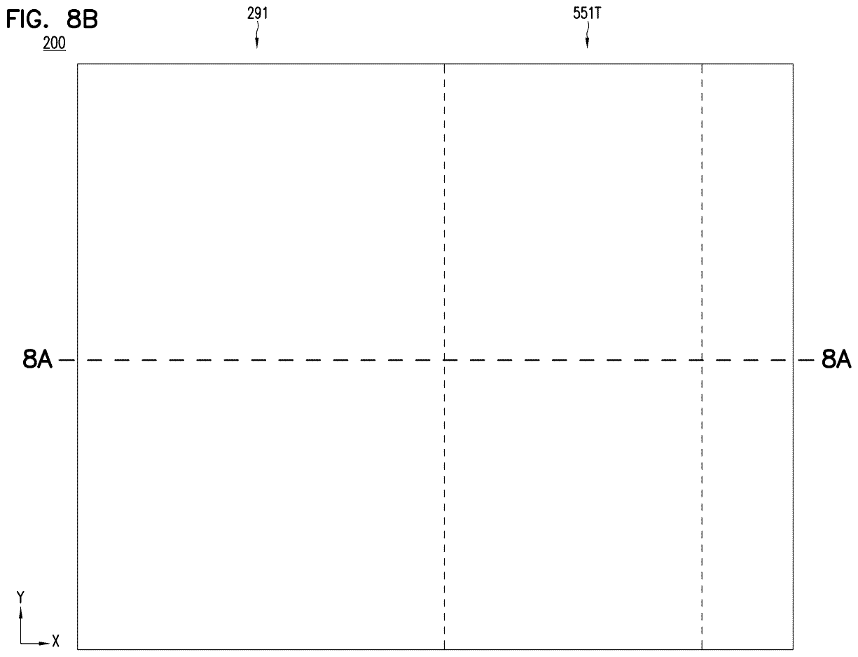

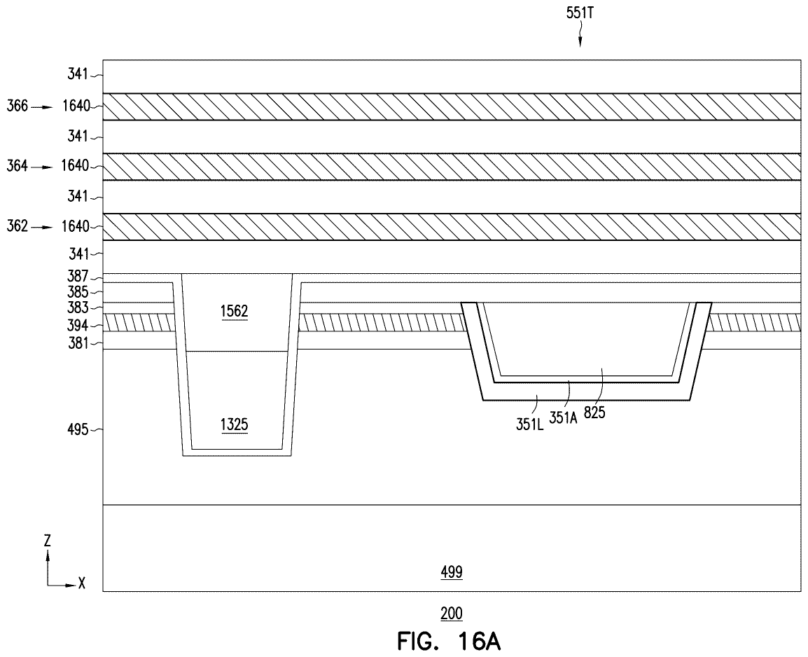

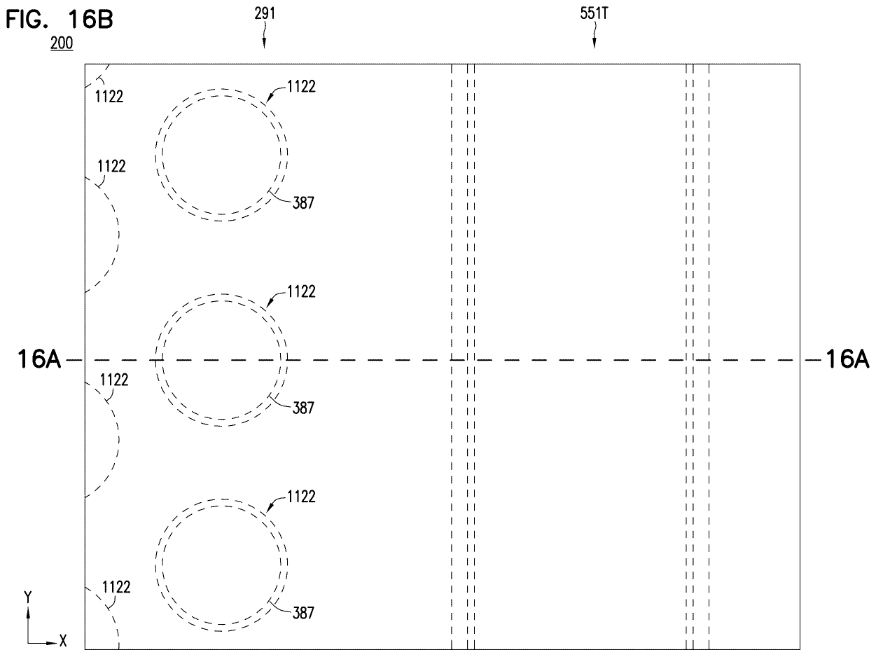

FIG. 8A and FIG. 8B show memory device 200 after a material 825 is formed over material 721 and filled trench 551T. Material 825 can be different from material 341 (e.g., different from silicon dioxide) formed in FIG. 16A and different from material (e.g., silicon nitride) 1640 formed in FIG. 16A. For example, material 825 can include titanium nitride (TiN), tungsten (W), a combination of TiN and W, or other materials.

FIG. 9A and FIG. 9B show memory device 200 after liner 351L and portion (dielectric portion) 351A is formed. Liner 351L and portion 351A are part of dielectric structure 351 (formed in FIG. 23A). In FIG. 9A, forming liner 351L can include removing a portion (e.g., a portion outside trench 551T) of material 651. As shown in FIG. 9A, a remaining portion (e.g., a portion inside trench 551T) of material 651 forms liner 351L. Forming portion 351A can include removing a portion (e.g., a portion outside trench 551T) of material 721. As shown in FIG. 9A, a remaining portion (e.g., a portion inside trench 551T) of material 721 forms portion 351A. The processes associated with FIG. 9A and FIG. 9B also include removing a portion of material 825. FIG. 9A shows a remaining portion of material 825 in trench 551 T. A CMP process can be used to remove the portion of materials 825, 721, and 651. In the processes associated with FIG. 9A, the CMP can stop at material 383, such that liner 351L and portion 351A in trench 551T can have structures shown in FIG. 9A.

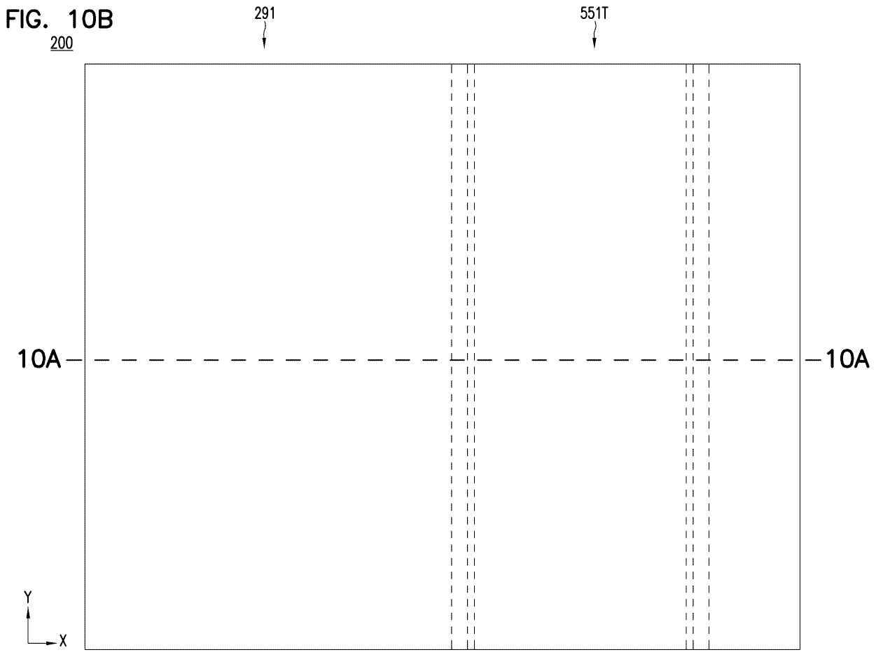

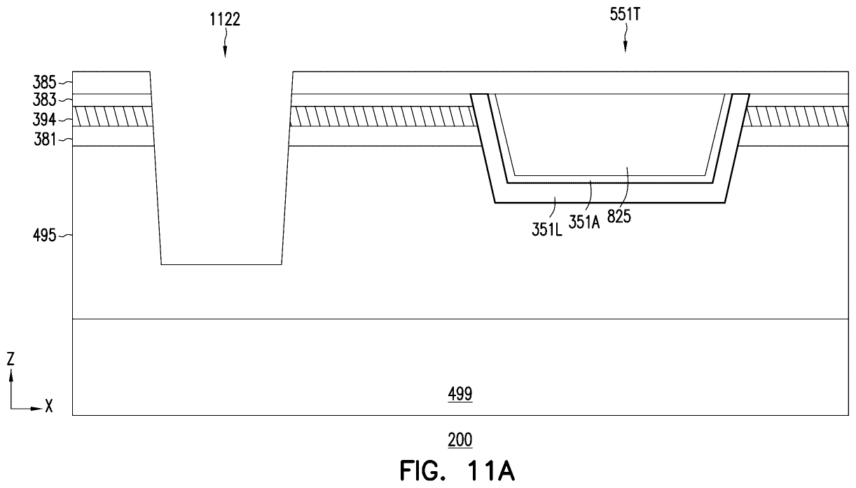

FIG. 10A and FIG. 10B show memory device 200 after material (e.g., silicon dioxide) 385 is formed over material 383 and over material 825 in trench 551T.

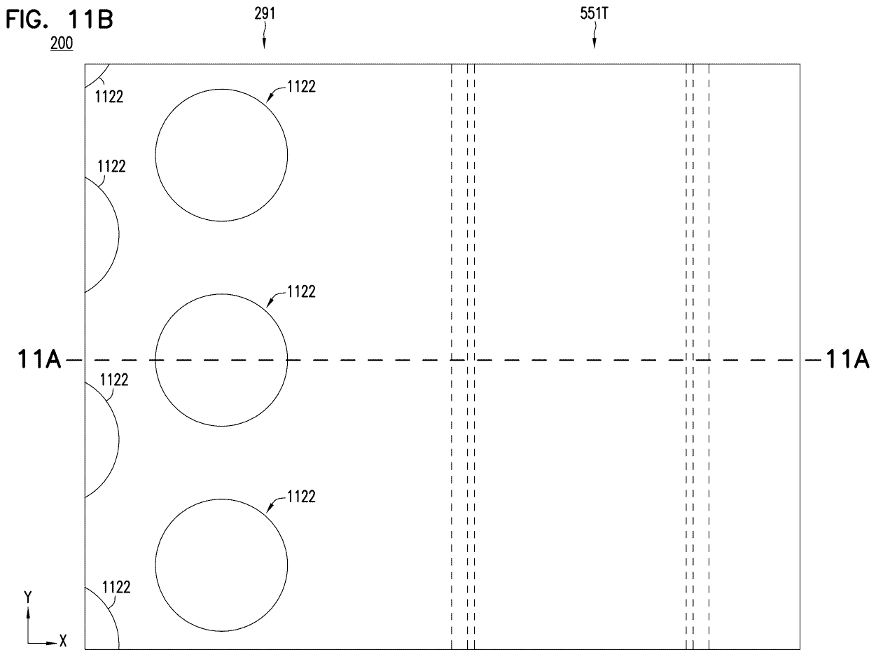

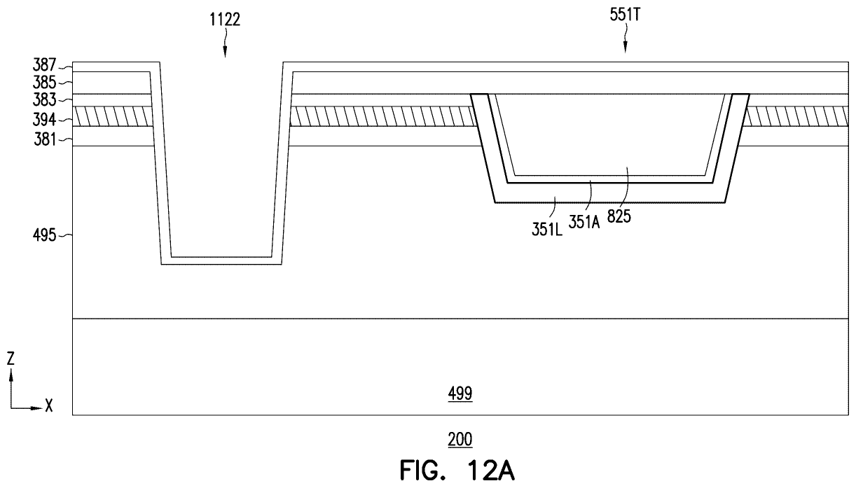

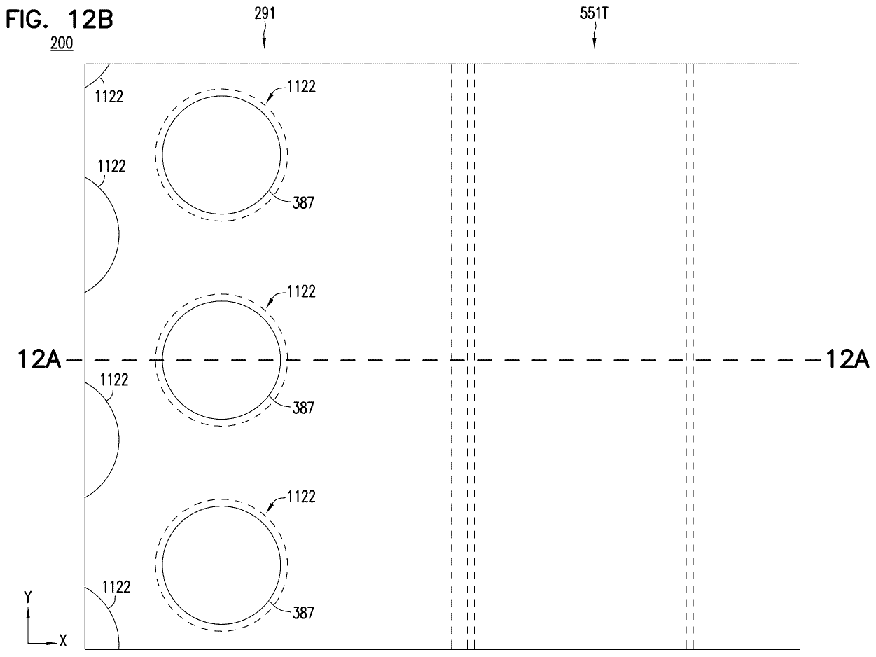

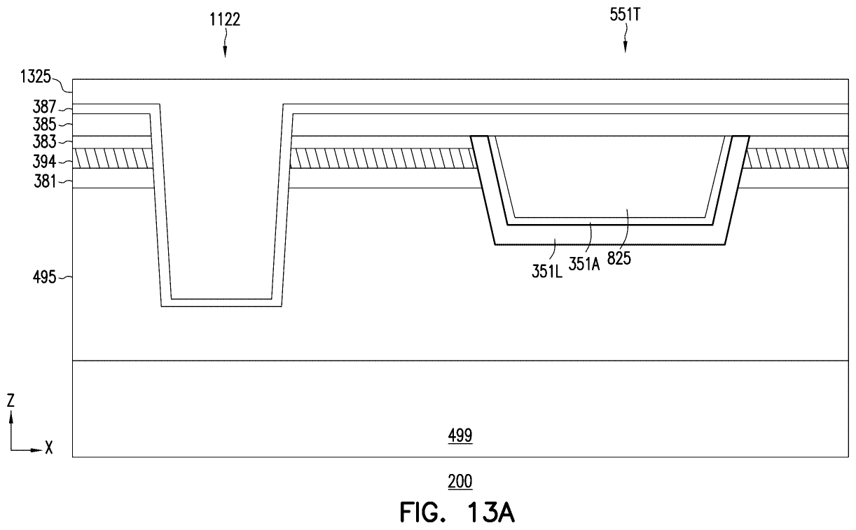

FIG. 11A and FIG. 11B show memory device 200 after openings (e.g., holes) 1122 are formed. In subsequent processes (FIG. 12A through FIG. 18B), part of pillars (memory cell pillars) 322 of memory device 200 can be formed at the locations of openings 1122 (FIG. 11B). As shown in FIG. 11B, openings 1122 can be formed in rows (in the X-direction) adjacent trench 551T. Only some of openings 1122 are shown in FIG. 11B. Forming openings 1122 can include removing (e.g., etching) a portion of each of materials 385, 383, 394, 381, and 495. As shown in FIG. 11A, openings 1122 can extend through materials 385, 383, 394, and 381 and extend partially into material 495.

FIG. 12A and FIG. 12B show memory device 200 after memory device 200 after material (e.g., dielectric liner) 387 is formed. As shown in FIG. 12A and FIG. 12B, material 387 can form a dielectric liner in a respective opening 1122. Forming material 387 can include forming (e.g., depositing) a dielectric material (e.g., silicon dioxide) in openings 1122 and over material 385.

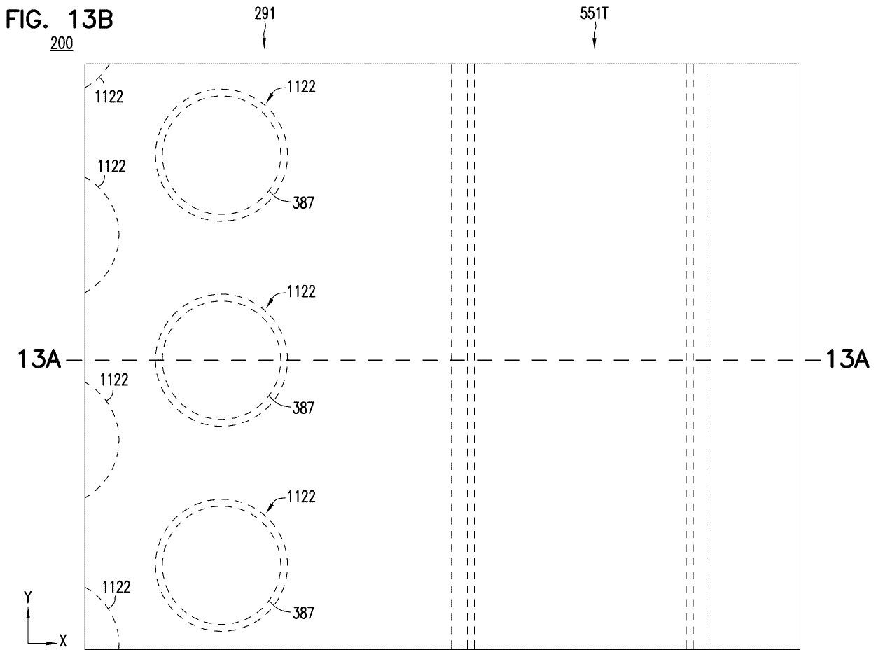

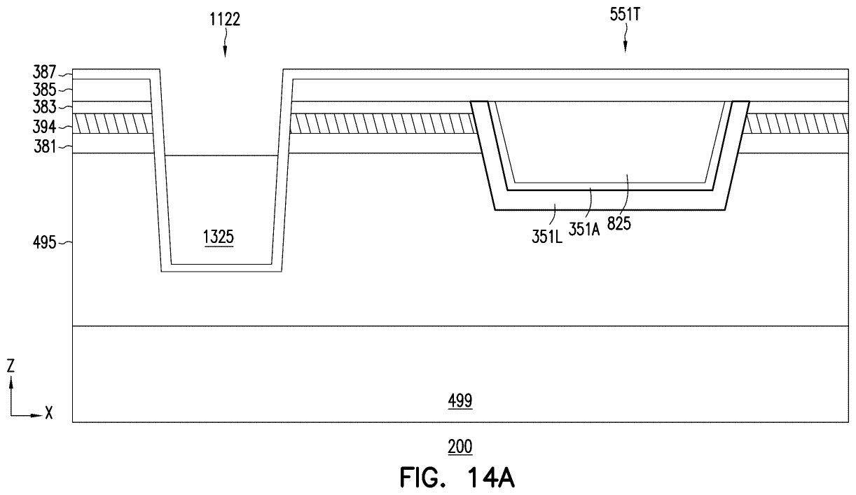

FIG. 13A and FIG. 13B show memory device 200 after a material 1325 is formed over material 387 and filled openings 1122. Material 1325 is different from material 387. Material 1325 can be similar to or the same as material 825. For example, material 1325 can include titanium nitride (TiN), tungsten (W), a combination of TiN and W, or other materials.

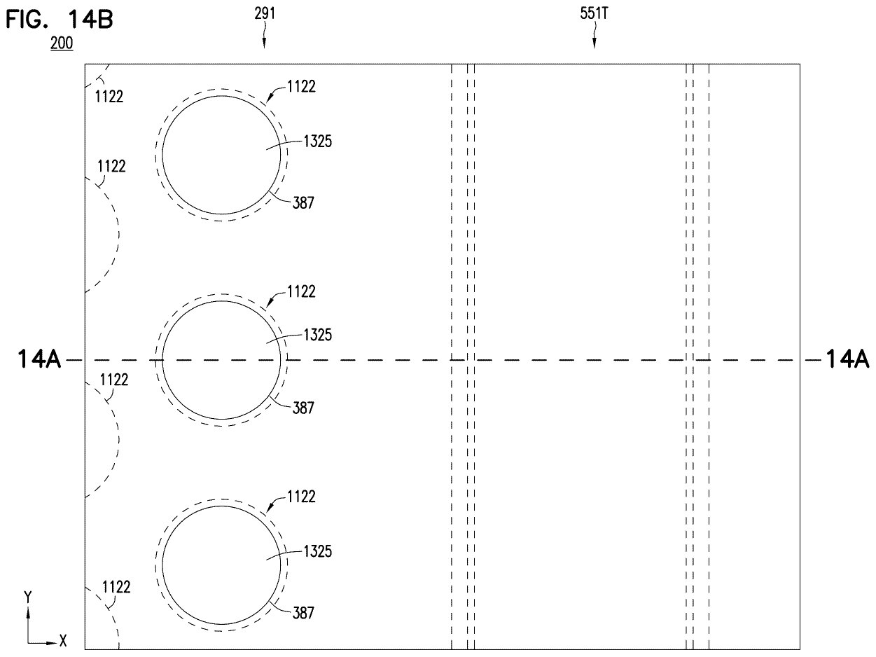

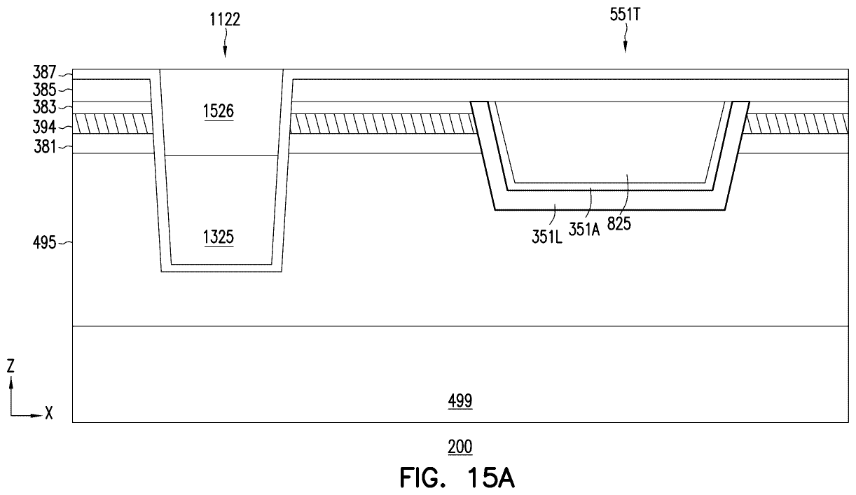

FIG. 14A and FIG. 14B show memory device 200 after a portion of material 1325 is removed from (recessed at) openings 1122. A remaining portion of material 1325 in openings 1122 can have a surface (top surface, not labeled) below a top surface (not labeled) one of materials 385, 383, 394, 381, and 495.

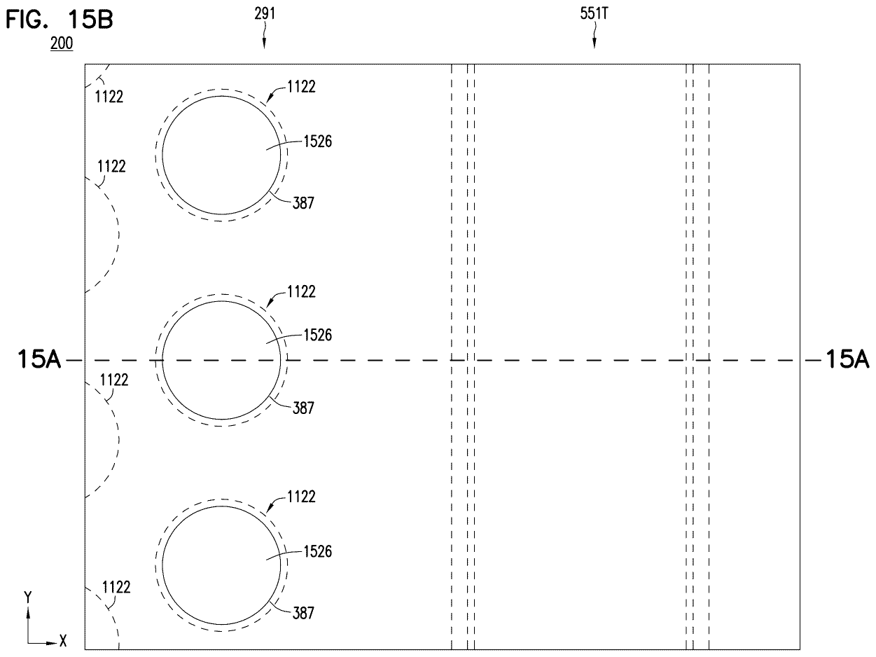

FIG. 15A and FIG. 15B show memory device 200 after a material 1526 is formed in openings 1120 over material 1325. Material 1526 can be different from material 1325. Material 15265 can be different from material 341 (e.g., silicon dioxide) formed in FIG. 16A and different from material (e.g., silicon nitride) 1640 formed in FIG. 16A. An example of material 1526 includes carbon.

FIG. 16A and FIG. 16B show memory device 200 after tiers of dielectric materials 341 and 1640 are formed over other materials and over the locations of openings 1122 and trench 551T. Dielectric materials 341 and 1640 can be sequentially formed one material after another, such that dielectric materials 341 and 1640 can be interleaved with each other in different levels of memory device 200 as shown in FIG. 16A. FIG. 16A shows a few levels 362, 364, and 366 of memory device 200 that are the same as those shown in FIG. 3C, FIG. 3D, and FIG. 3E.

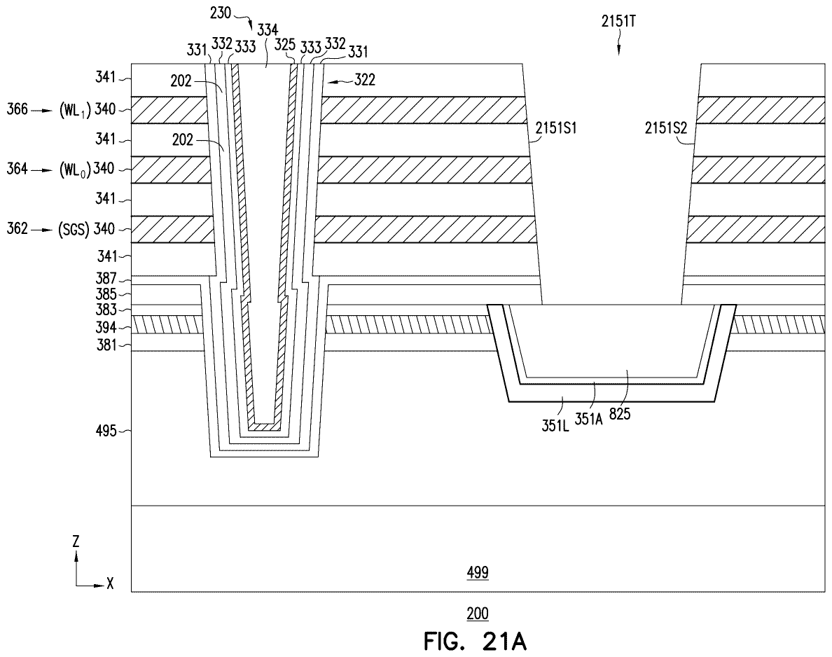

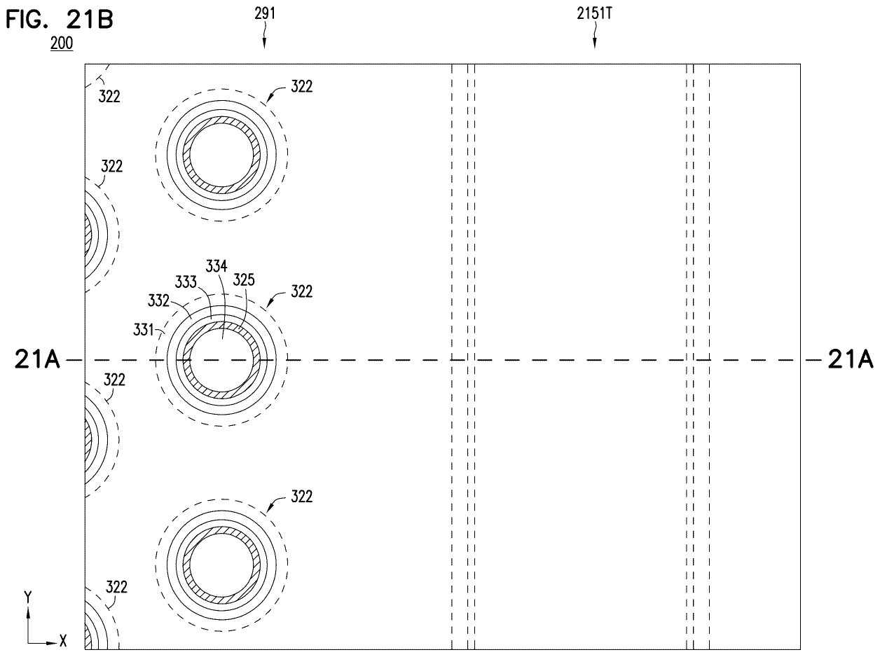

In FIG. 16A, dielectric materials 341 can include respective levels of silicon dioxide. Materials 1640 can include respective levels of silicon nitride. In subsequent processes, materials (e.g., silicon nitride) 1640 can be removed (e.g., exhumed) and replaced with respective levels of conductive material (e.g., tungsten or tungsten-based material or other conductive materials) to form respective control gates of memory device 200. FIG. 21A shows some of the control gates (associated with signals WL₀ and WL₁) formed on levels 364 and 366. In FIG. 16A, materials (e.g., silicon dioxide) 341 can correspond to dielectric materials 341 of memory device 200 (e.g., FIG. 3C, FIG. 3D, and FIG. 3E). Dielectric materials 341 can be formed to provide separation between the control gates (e.g., the control gates associated with signals WL₀ and WL₁ in FIG. 21A) of memory device 200 that are subsequently formed (formed in FIG. 21A).

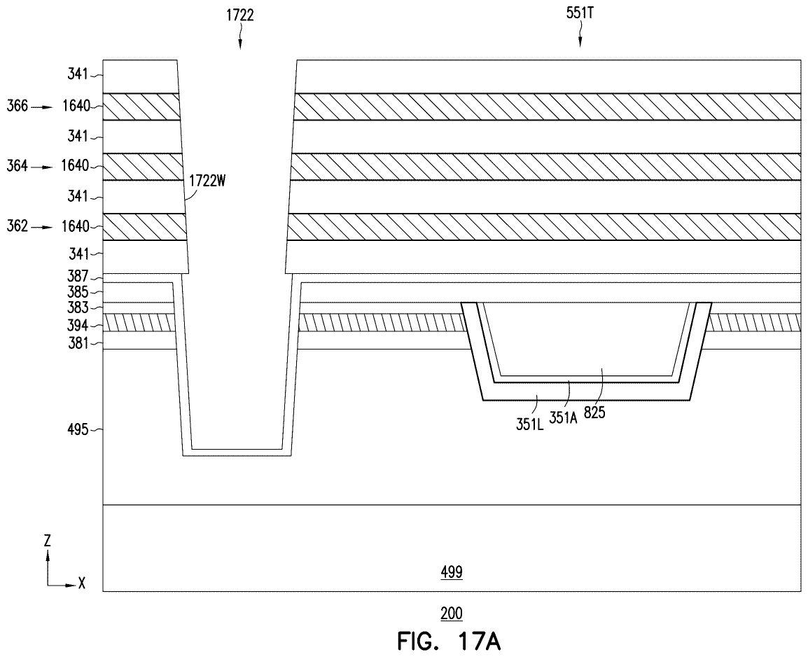

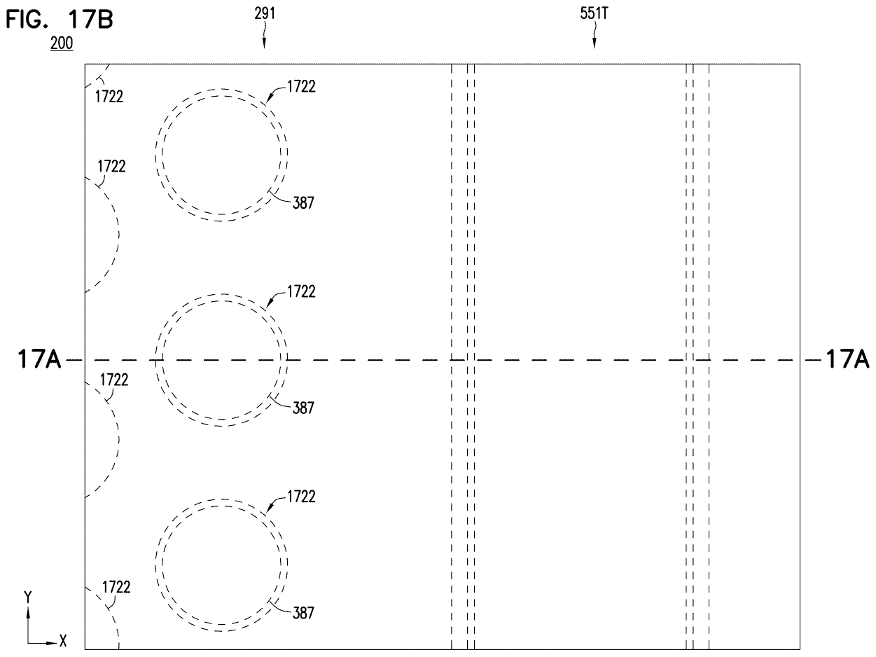

FIG. 17A and FIG. 17B show memory device 200 after openings (e.g., holes) 1722 are formed in the tiers of dielectric materials 341 and 1640. As shown in FIG. 16B, FIG. 17A, and FIG. 17B, openings 1722 can be formed over the locations of openings 1122 (e.g., can be aligned with openings 1122). Thus, the location of a respective opening 1722 can be a combination of the location of one opening 1120 (formed in FIG. 11A) and the location of the respective opening 1722 (formed in FIG. 17A). As shown in FIG. 17A, a respective opening 1722 can include a sidewall 1722W formed by part of the tiers of dielectric materials 341 and 1460 and part of material (e.g., dielectric liner) 387. Forming openings 1722 can include removing (e.g., etching) a portion of the tiers of dielectric materials 341 and 1640 at the location of openings 1722 and removing materials 1562 and 1325 at the locations of openings 1722.

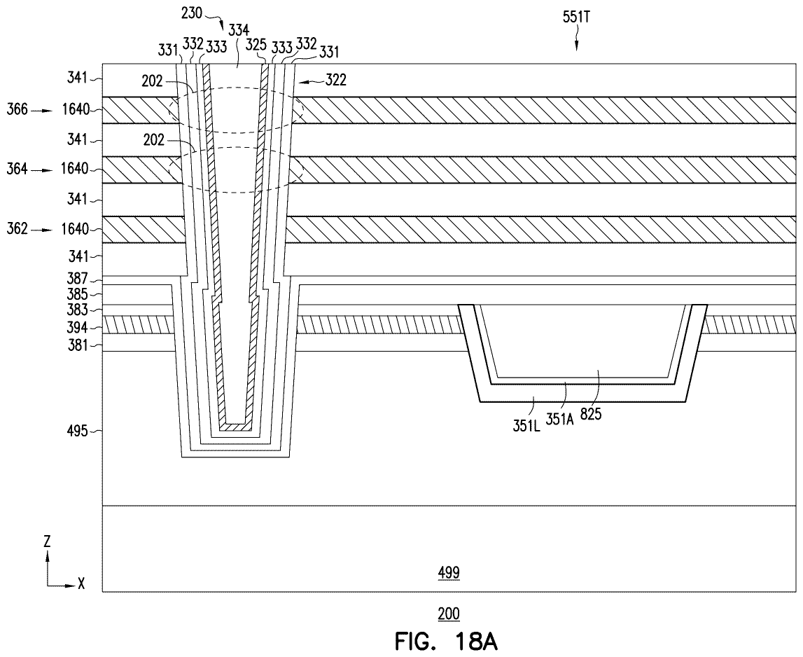

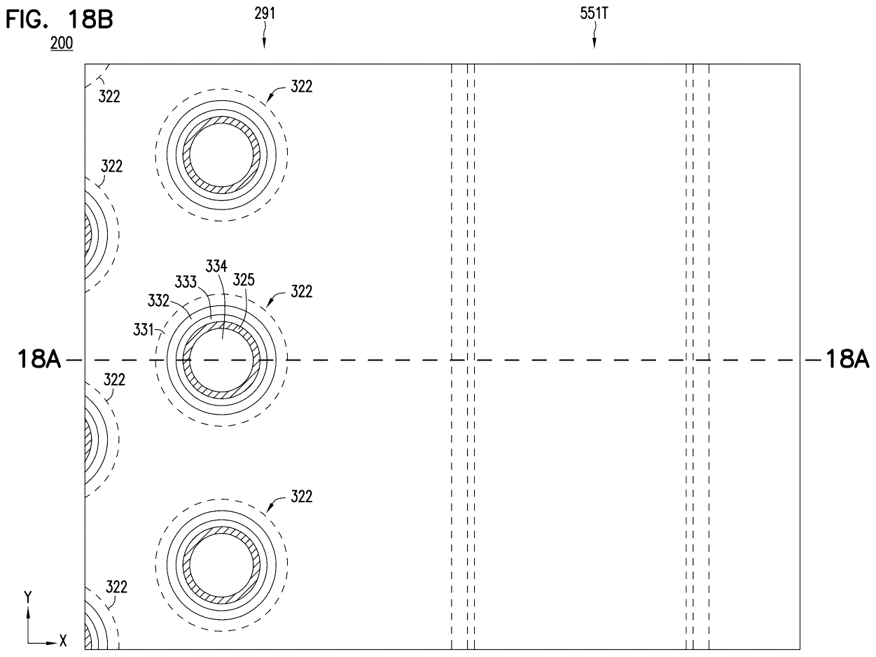

FIG. 18A and FIG. 18B show memory device 200 after pillars (memory cell pillars) 322 of memory cell string 230 are formed in respective openings 1722 (labeled in FIG. 17A). As shown in FIG. 18A, pillar 322 is associated with memory cells 202. Pillar 322 can extend through the tiers of dielectric materials 341 and 1640, and materials 387, 385, 383, 394, and 381. Pillar 322 can also extend at least partially into material 495.

The pillar 322 in FIG. 18A is the same as pillar 322 in FIG. 3D and FIG. 3E. As shown in FIG. 18A, pillar 322 includes dielectric portion 331, charge storage portion 332, dielectric portion 333, conductive channel portion 325, and dielectric portion 334. The portions (e.g., materials) of pillar 322 can be formed (e.g., sequentially formed) one at a time. For example, a material (or materials) for dielectric portion 331 can be formed (e.g., deposited) on sidewall 1722W (labeled in FIG. 17A) of opening 1722, then materials for other portions can be formed following the order of charge storage portion 332, dielectric portion 333, conductive channel portion 325, and dielectric portion 334. FIG. 18A shows an example structure of pillar 322 of memory cell string 230. However, pillar 322 can have a different structure (e.g., TANOS, SONOS, or floating-gate structure).

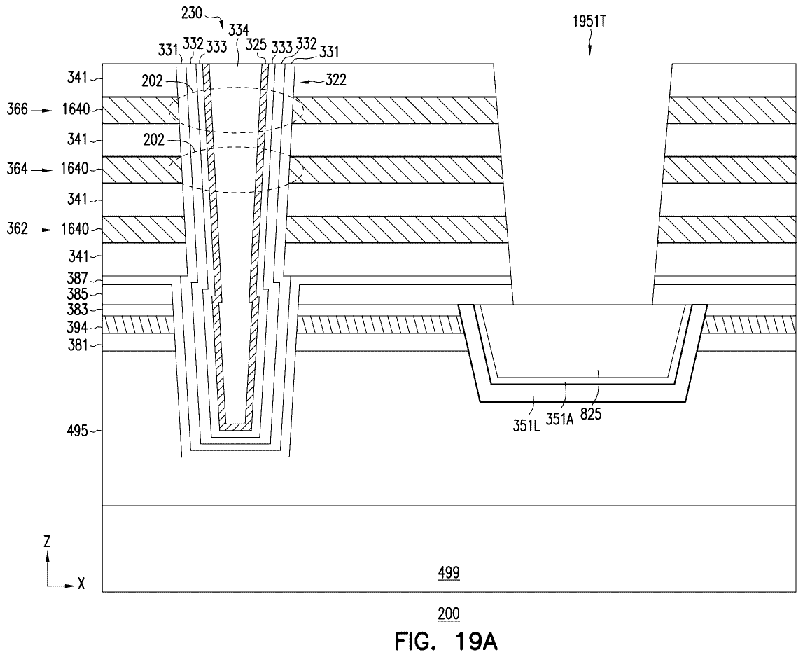

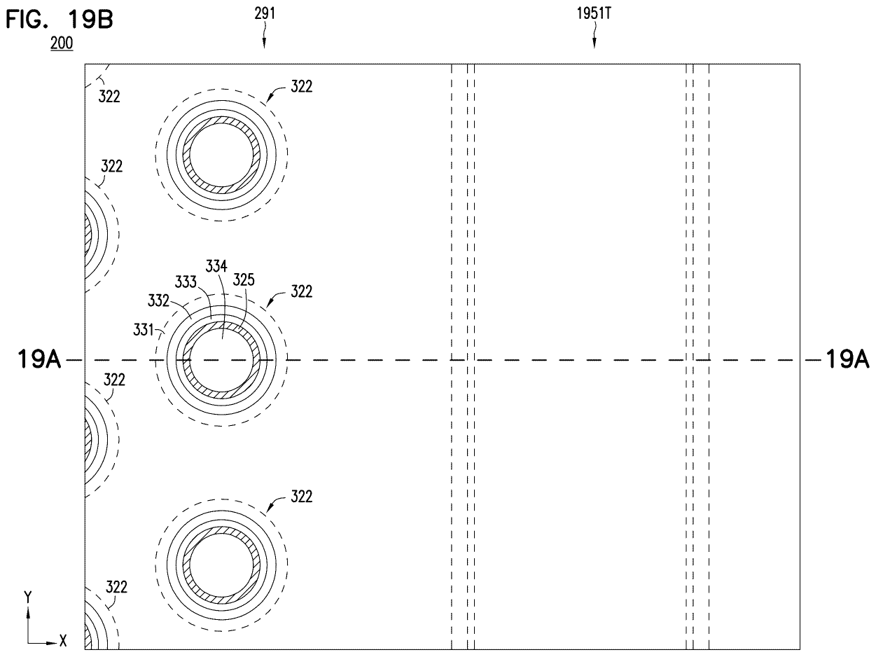

FIG. 19A and FIG. 19B show memory device 200 after a trench 1951T is formed in the tiers of dielectric materials 341 and 1640 over the location of opening 551T (labeled in FIG. 18A). The processes associated with FIG. 19A and FIG. 19B can include removing a portion of the tiers of dielectric materials 341 and 1640 at the location of trench 1951T. As shown in FIG. 19A, a portion of material 825 can be exposed at trench 1951T.

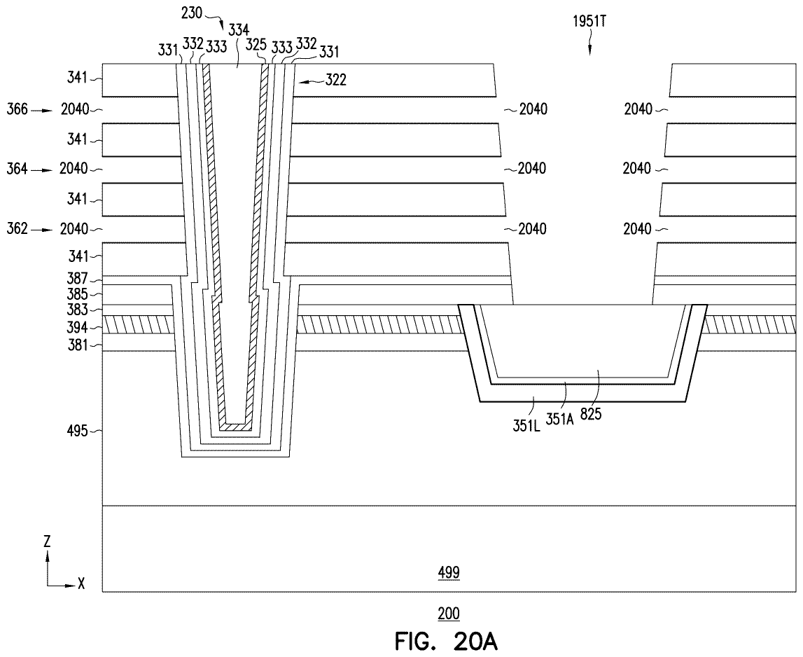

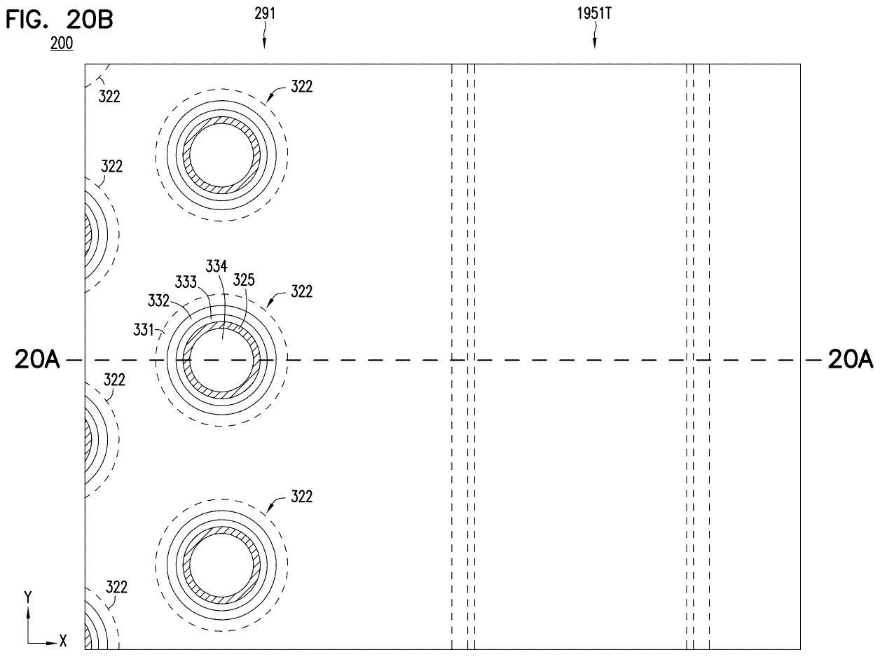

FIG. 20A and FIG. 20B show memory device 200 after materials (e.g., silicon nitride) 1640 in FIG. 19A are removed (e.g., exhumed) from locations 2040 (FIG. 20A). Locations 2140 are voids (e.g., empty spaces) that were occupied by materials 1640 in FIG. 19A.

FIG. 21A and FIG. 21B show memory device 200 after material (or materials) 340 is formed in locations 2040 (labeled in FIG. 21). Forming material 340 can include forming (e.g., depositing) a conductive material (e.g., a single conductive material) or alternatively a combination of conductive materials (e.g., multiple layers of conductive) in locations 2140. For example, forming material 340 can include forming (e.g., depositing) tungsten (or another metal) in locations 2040. In another example, forming material 340 can include forming (e.g., depositing) multiple materials (one at a time) in locations 2140. For example, the processes in FIG. 21A can include depositing aluminum oxide (AlO) on sidewalls of locations 2140, depositing titanium nitride (TiN) adjacent (e.g., conformal to) the aluminum oxide, and then depositing tungsten (W) or other suitable conductive material adjacent (e.g., conformal to) the titanium nitride. Thus, in an example, material 340 can include a combination of (multiple layers of) AlO, TiN, and W.

Material 340 at respective tiers (e.g., at levels 362, 364, and 366) of memory device 200 in FIG. 21A can correspond to respective conductive materials on levels (e.g., tiers) 362, 364, and 366 of FIG. 3C, FIG. 3D, and FIG. 3E. For example, in FIG. 21A, materials 340 on levels 362, 364, and 366 can correspond to conductive materials 340_{SGS}, 340₀, and 340₁, respectively, of FIG. 3C, FIG. 3D, and FIG. 3E. Thus, as shown in FIG. 21A, control gates (associated with signals WL₀ and WL₁) and a select gate (e.g., source select gate associated with signal SGS) are formed from material 340 on respective levels (e.g., levels 362, 364, and 366) of memory device 200.

As shown in FIG. 21A, a trench 2151T is also formed at the location of trench 1951T (labeled in FIG. 20A). Trench 2151T can include sidewalls 2151S1 and 2151S2 that are formed by respective portions of materials 340 and 341 at trench 2151T.

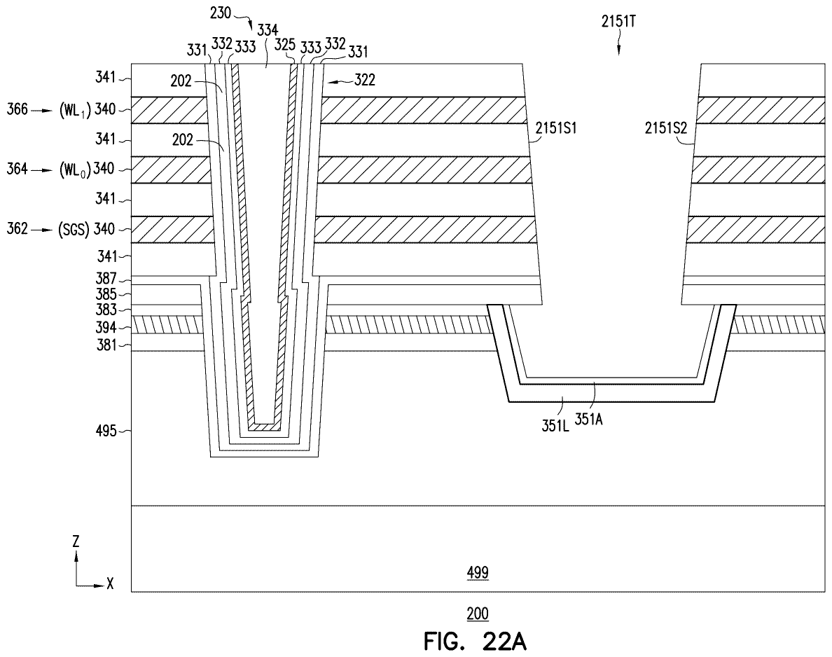

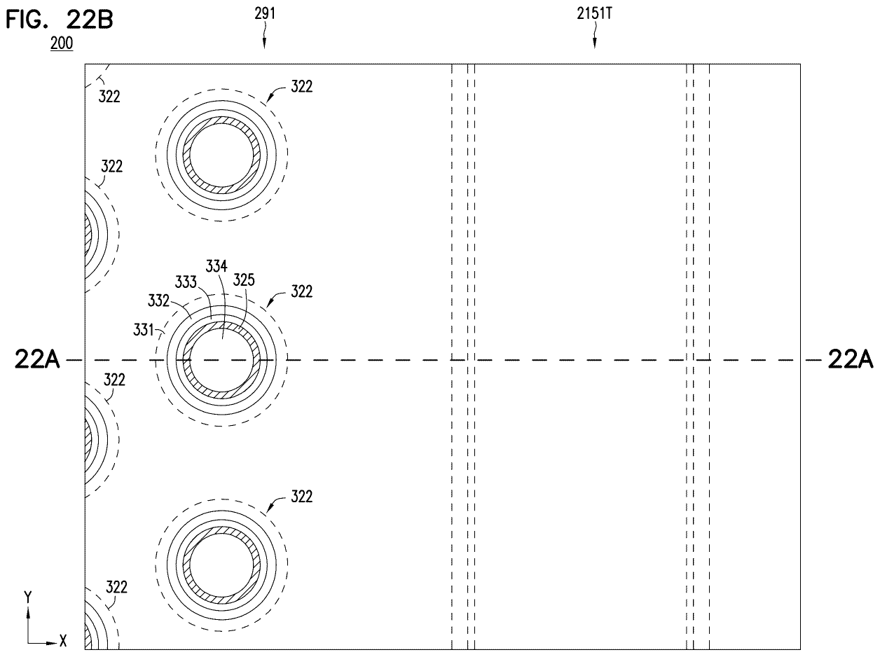

FIG. 22A and FIG. 22B show memory device 200 after material 835 is removed from trench 2151T.

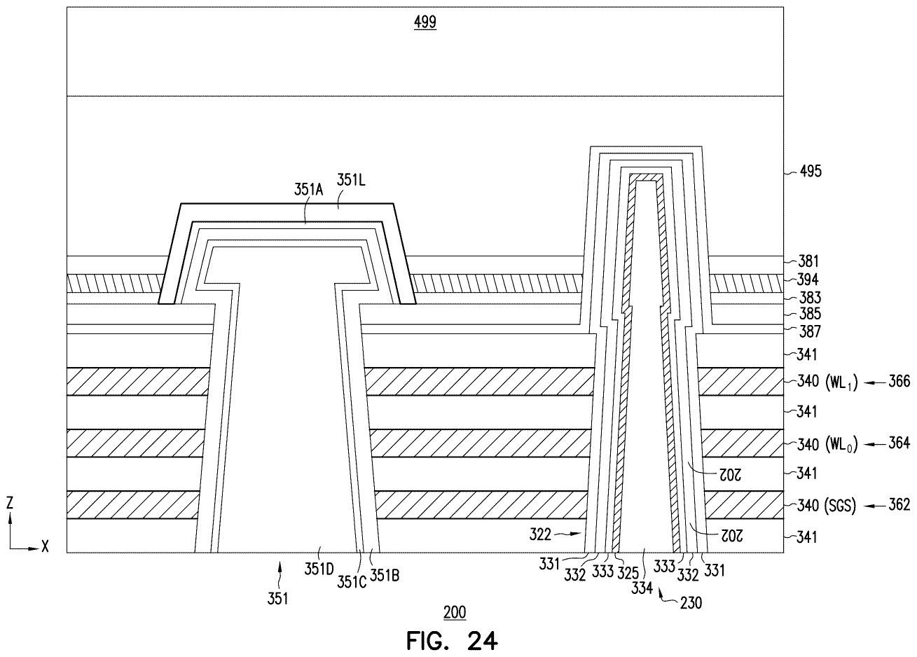

FIG. 23A and FIG. 24B show memory device 200 after dielectric structure 351 is formed in trench 2151T. As shown in FIG. 23A, dielectric structure 351 can include liner 351L (formed in FIG. 9A), portion 351A (formed in FIG. 9A) processes described above), and portions 351B, and 351C, and 351D (formed in FIG. 23A). Portions 351B, and 351C, and 351D are described above with reference to FIG. 3D. In FIG. 23A, portions 351B, and 351C, and 351D can be sequentially formed in trench 2151T. For example, the material (e.g., dielectric material) for portion 351B can be formed (e.g., deposited) over portion 531A and on sidewalls 2151S1 and 2151S2 (labeled in FIG. 22A) of trench 2151T. The material (e.g., dielectric material) for portion 351C can be formed (e.g., deposited) on portion 351C. Then, the material for portion 351C can be formed (e.g., filled) in trench 2251T.

FIG. 24 shows memory device 200 after it is rotated (flipped over) 180 degrees in the X-direction.

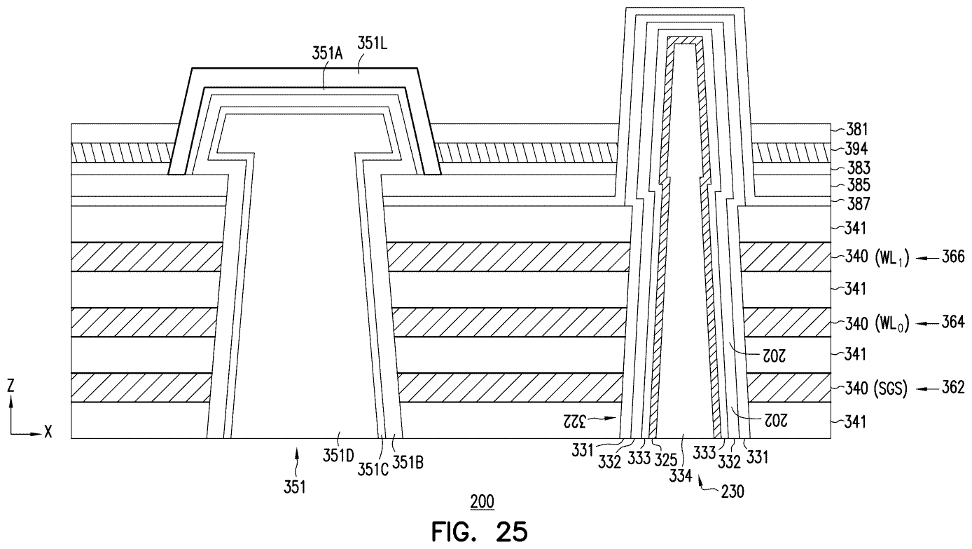

FIG. 25 shows memory device 200 after structure 499 and material 495 are removed. As shown in FIG. 25A, liner 351L and a portion of material 387 are exposed after the removal of structure 499 and material 495.

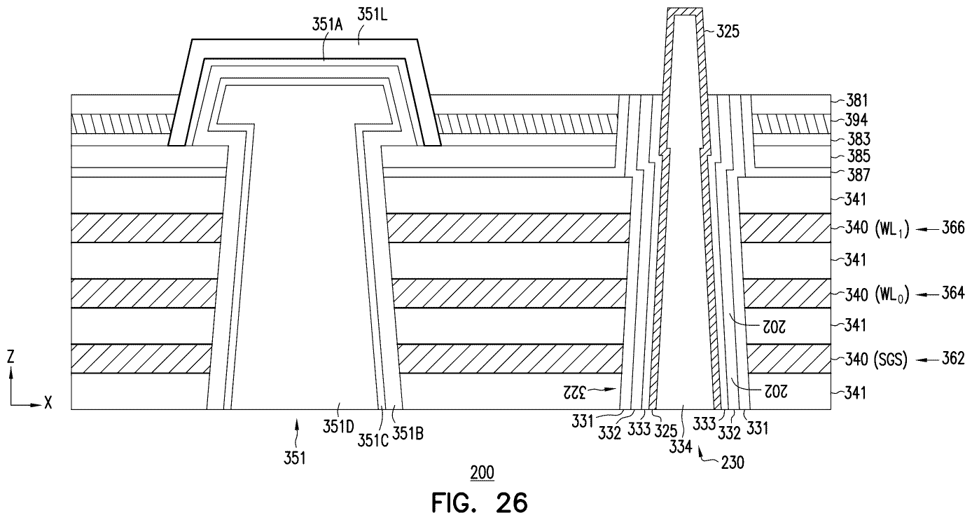

FIG. 26 shows memory device 200 after a portion of material 387 and a portion of pillar 322 are removed (e.g., cut) to expose conductive channel portion 325 of pillar 322. Removing a portion of pillar 322 can include removing a portion of each of portions 331, 332, and 333.

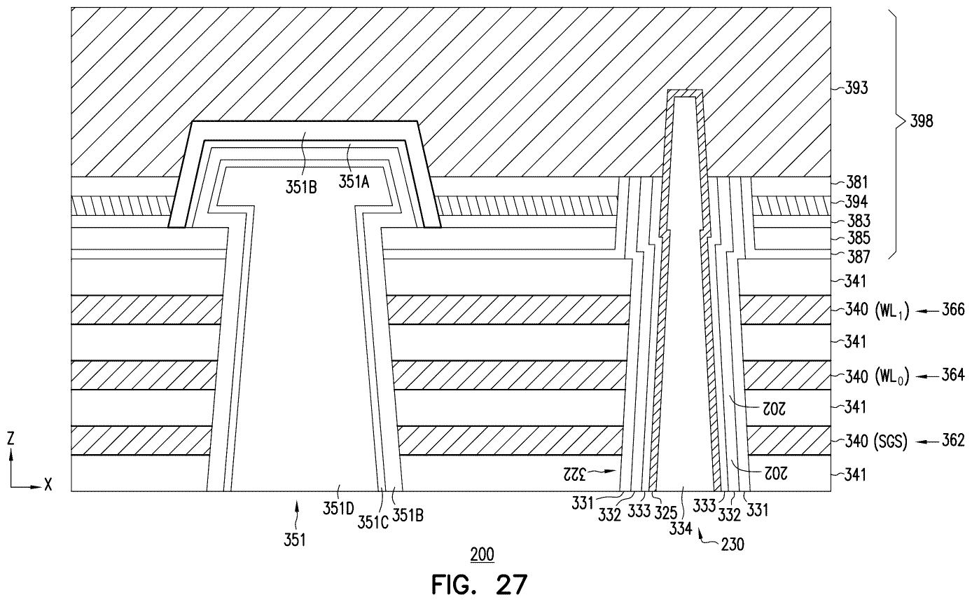

FIG. 27 shows memory device 200 after conductive region 393 is formed. Conductive region 393 is the same as conductive region 393 of memory device 200 shown in FIG. 3D and FIG. 3C. Thus, in the processes associated with FIG. 4A through FIG. 27, liner 351L (formed in FIG. 9A) is formed before conductive region 393 (FIG. 27) is formed. In other words, conductive region 393 is formed after liner 351L is formed. Pillar 322 (formed in FIG. 18A) is formed before conductive region 393 (FIG. 27) is formed. In other words, conductive region 393 is formed after pillar 322 is formed.

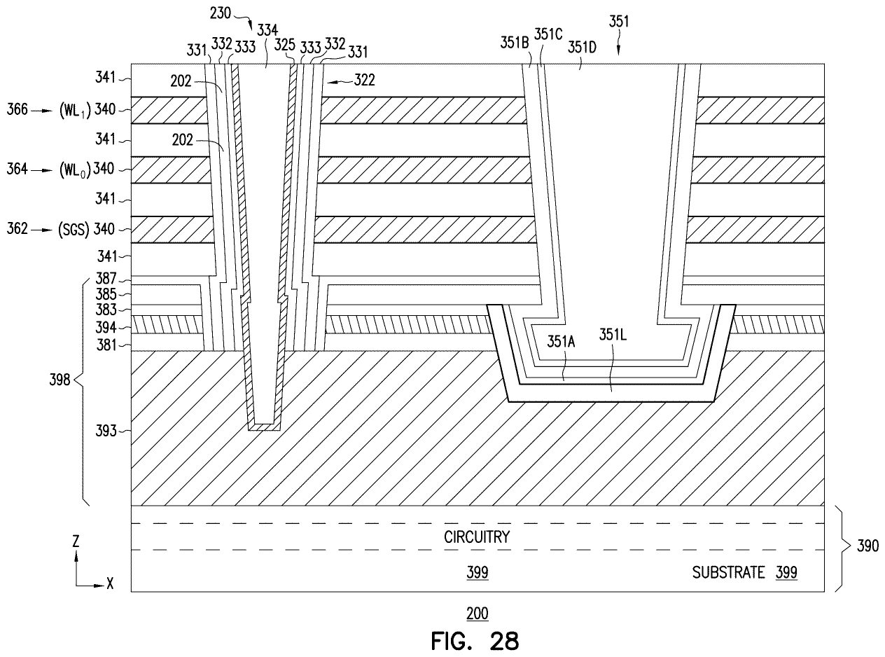

FIG. 28 shows memory device 200 after base structure 390 is formed adjacent conductive structure 393. FIG. 28 also shows memory device 200 after it is rotated (flipped over) 180 degrees in the X-direction. In FIG. 28, memory device 200 can be rotated 180 degrees after (or before) base structure 390 is formed. As shown in FIG. 28, base structure 390 include circuitry 395 formed in (or formed on) substrate 399. Base structure 390 is described above with reference to FIG. 3C.

The processes of forming memory device 200 described above with reference to FIG. 4A through FIG. 28 can include other processes to form a complete memory device (e.g., memory device 200). Such processes are omitted from the above description so as not to obscure the subject matter described herein.

Forming memory device 200 as described allows it to have improvements and benefits in comparison with some alternative techniques.

For example, liner 351L (FIG. 3D, FIG. 3C, and FIG. 9A) can be formed from silicon nitride, or silicon dioxide, or a combination (e.g., multiple layers) of silicon nitride and silicon dioxide. However, forming liner 351L from a material different from silicon nitride, silicon dioxide, or both, can improve the structure of memory device 200 adjacent (e.g., near the location of) liner 351L of dielectric structure 351. For example, liner 351L (having a material different from silicon nitride, silicon dioxide, or both) can protect other portions of dielectric structure 351 and other parts of memory device 200 adjacent dielectric structure 351 from corrosion during some of the processes of forming memory device 200, such as the processes associated with FIG. 20A and FIG. 25. Further, as described above, liner 351L can include a semiconductor material (e.g., polysilicon) and boron. Alternatively, liner 351L can include a semiconductor material and another material different from boron. However, forming liner 351L with a semiconductor material (e.g., polysilicon) and boron (as described above) can provide improved protection (against corrosion) relative to forming liner 351L with a semiconductor material and a material different from boron.

In another example, the inclusion of liner 351L allows material 383 (formed in FIG. 4A) to be relatively thin, thereby leading to cost savings. For example, the thickness (in the Z-direction) of material (e.g., silicon dioxide) 383 can be less than the thickness of material (e.g., polysilicon) 394. In an example, the thickness (in the Z-direction) of material 383 can be equal to or less than one-half of the thickness of material 394. For example, the thickness of material 394 can be in a range from 18 nanometer (nm) to 22 nm, and the thickness of material 383 can be in a range from 6 nm to 9 nm.

This description describes the thicknesses of materials and elements of memory device 200 as having specific thicknesses (e.g., specific values in nm) for example purposes. However, the materials and elements of memory device 200 can have thicknesses different from the example thicknesses described herein.

In another example, the inclusion of liner 351L allows portion (dielectric liner) 351A of dielectric structure 351 to be relatively thin, thereby leading to cost savings. For example, the thickness (in the Z-direction) of portion (e.g., silicon dioxide) 351A can be less than the thickness of material (e.g., polysilicon) 394 and less than the thickness of liner 351L. In an example, the thickness of liner 351L can be in a range from 18 nm to 22 nm, the thickness of material 394 can be in a range from 18 nm to 22 nm, and the thickness of portion 351A can be in a range from 5 nm to 7 nm.

In another example, the inclusion of liner 351L allows elimination of some processes in forming part of memory device 200. For example, to maintain the quality of the structure part of memory device 200 (e.g., pillar 322 and dielectric structure 351), the processes of removing material 495 in FIG. 25 may be performed in multiple process steps if liner 351L is not included in memory device 200. For example, in one process step, a portion of material 495 adjacent pillar 322 can be removed while the portion of material 495 adjacent dielectric structure 351 can remain (not removed). Then, in another process step, the portion of material 495 adjacent dielectric structure 351 can be removed. However, the inclusion of liner 351L allow material 495 (adjacent pillar 322 and adjacent dielectric structure 351) to be removed in fewer process steps (e.g., removed in a single process step (e.g., the process associated with FIG. 25)). Such fewer process steps can lead to cost savings.

In another example, the inclusion of liner 351L allows the thickness of material 495 to be relative thinner. This can also lead to cost savings.

Further, since liner 351L is formed to protect (e.g., protect from corrosion) part of memory device 200 during some of the processes (as described above), the structure of part of the memory device 200 can be improved. This can improve the reliability and performance of memory device 200.

The illustrations of apparatuses (e.g., memory devices 100 and 200) and methods (e.g., method of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., a computer, a cellular phone, or other electronic systems) that includes a device such as any of memory devices 100 and 200.

Any of the components described above with reference to FIG. 1 through FIG. 28 can be implemented in a number of ways, including simulation via software. Thus, apparatuses, e.g., memory devices 100 and 200 or part of each of these memory devices described above, may all be characterized as “modules” (or “module”) herein. Such modules may include hardware circuitry, single-and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100 and 200 may be included in apparatuses (e.g., electronic circuitry) such as high-speed computers, communication and signal processing circuitry, single-or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 28 include apparatuses and methods of forming the apparatuses. One of the methods includes: a structure including a conductive region; first memory cells and first control gates associated with the first memory cells located over the structure; second memory cells and second control gates associated with the second memory cells located over the structure; and a dielectric structure between the first memory cells and the second memory cells and separating the first control gates from the second control gates. The dielectric structure extends into the conductive region and includes a liner adjacent a portion of the conductive region. The liner includes a dielectric constant different from a dielectric constant of silicon dioxide. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a structure including a conductive region;
first memory cells and first control gates associated with the first memory cells located over the structure;
second memory cells and second control gates associated with the second memory cells located over the structure; and
a dielectric structure between the first memory cells and the second memory cells and separating the first control gates from the second control gates, the dielectric structure extending into the conductive region and including a liner adjacent a portion of the conductive region, the liner including a dielectric constant different from a dielectric constant of silicon dioxide.

2. The apparatus of claim 1, wherein the dielectric constant of the liner is different from a dielectric constant of silicon nitride.

3. The apparatus of claim 1, wherein:
the structure includes a level of dielectric material, and a level of polysilicon material adjacent the level of dielectric material; and
the dielectric structure extends through the level of dielectric material and the level of polysilicon material.

4. The apparatus of claim 3, wherein:
the structure includes an additional level of dielectric material adjacent the level of polysilicon material;
the level of polysilicon material is between the level of dielectric material and the additional level of dielectric material; and
the dielectric structure extends through the additional level of dielectric material.

5. The apparatus of claim 4, wherein the dielectric structure includes a first sidewall adjacent the first control gates, and a second wall adjacent the second control gates.

6. The apparatus of claim 1, further comprising a substrate, and circuitry formed in the substrate and adjacent the conductive region.

7. An apparatus comprising:
a structure including a conductive region;
levels of first conductive materials interleaved with levels of first dielectric materials;
a first memory cell pillar extending through the levels of first conductive materials and the levels of first dielectric materials, the first memory cell pillar extending into the conductive region;
levels of second conductive materials interleaved with levels of second dielectric materials;
a second memory cell pillar extending through the levels of second conductive materials and the levels of second dielectric materials, the second memory cell pillar extending into the conductive region; and
a dielectric structure separating the first conductive materials from the second conductive materials, the dielectric structure extending into the conductive region and including a liner adjacent a portion of the conductive region, the liner including a boron material.

8. The apparatus of claim 7, wherein the liner includes a combination of a semiconductor material and the boron material.

9. The apparatus of claim 8, wherein the semiconductor material includes polysilicon.

10. The apparatus of claim 7, wherein the dielectric structure includes a dielectric portion adjacent the liner.

11. The apparatus of claim 10, wherein the dielectric structure includes an additional dielectric portion between the dielectric portion and the liner.

12. The apparatus of claim 7, wherein:
the structure includes a level of dielectric material, and a level of polysilicon material adjacent the level of dielectric material;
the first memory cell pillar includes a first conductive polysilicon portion adjacent the conductive region; and
the second memory cell pillar includes a second conductive polysilicon portion adjacent the conductive region.

13. The apparatus of claim 12, wherein:
the structure includes an additional level of dielectric material adjacent the level of polysilicon material;
the level of polysilicon material is between the level of dielectric material and the additional level of dielectric material;
the first memory cell pillar extends through the additional level of dielectric material; and
the second memory cell pillar extends through the additional level of dielectric material.

14. The apparatus of claim 7, wherein;
the structure includes a level of dielectric material, and a level of polysilicon material adjacent the level of dielectric material; and
dielectric structure extends through the level of dielectric material and the level of polysilicon material.

15. The apparatus of claim 14, wherein:
the structure includes an additional level of dielectric material adjacent the level of polysilicon material;
the level of polysilicon material is between the level of dielectric material and the additional level of dielectric material; and
the dielectric structure extends through the additional level of dielectric material.

16. The apparatus of claim 7, wherein:
the levels of first conductive materials form respective control gates associated memory cells of the first memory cell pillar; and
the levels of second conducive materials form respective control gates associated memory cells of the second memory cell pillar.

17. A method comprising:
forming first memory cells and first control gates associated with the first memory cells;
forming second memory cells and second control gates associated with the second memory cells; and
form a dielectric structure between the first memory cells and the second memory cells and to separate the first control gates from the second control gates, wherein the dielectric structure is formed to include a liner in a portion of the dielectric structure, and the liner includes a boron material.

18. The method of claim 17, wherein forming dielectric structure includes:
forming a dielectric portion of the dielectric structure adjacent the liner.

19. The method of claim 17, further comprising:
forming a conductive region after the liner is formed, wherein the conductive region contacts the liner.

20. The method of claim 18, wherein further comprising:
forming a memory cell pillar associated with the first memory cells, wherein the memory cell pillar is formed before the conductive region is formed, and the memory cell pillar includes a conductive polysilicon portion contacting the conductive region.
